(19) United States
(12) Patent Application Publication
(10) Pub. No.: US 2012/0229224 A1
(43) Pub. Date: Sep. 13, 2012

(54) METHOD OF MANUFACTURING PIEZOELECTRIC VIBRATING REED, APPARATUS OF MANUFACTURING PIEZOELECTRIC VIBRATING REED, PIEZOELECTRIC VIBRATING REED, PIEZOELECTRIC VIBRATOR, OSCILLATOR, ELECTRONIC APPARATUS, AND RADIO-CONTROLLED TIMEPIECE

(76) Inventor: Masayuki KAWAGUCHI, Chiba-shi (JP)

(21) Appl. No.: 13/411,948

(22) Filed: Mar. 5, 2012

(30) Foreign Application Priority Data
Mar. 7, 2011 (JP) 2011-049451

(51) Int. Cl. H03B 5/30; H01L 41/22

(52) U.S. Cl. 331/156; 29/25.35

(57) ABSTRACT

A photoresist film forming process to form a film through a spin coating method is included, a plurality of groove portions and a plurality of wall portions are formed in an upper surface of a flow regulating plate, among the plurality of groove portions, the diameter of the outer side surface of a first groove portion is set to be smaller than the longest distance from the rotation center to the outer edge of the square wafer, and is set to be larger than the shortest distance from the rotation center to the outer edge of the square wafer, and among the plurality of groove portions, the diameter of the outer side surface of a second groove portion is set to be smaller than the shortest distance from the rotation center to the outer edge of the square wafer.

### RELATED APPLICATIONS

This application claims priority under 35 U.S.C. §119 to Japanese Patent Application No. 2011-049451 filed on Mar. 7, 2011, the entire content of which is hereby incorporated by reference.

### BACKGROUND OF THE INVENTION

1. Field of the Invention

The present invention relates to a method of manufacturing a piezoelectric vibrating reed, an apparatus for manufacturing a piezoelectric vibrating reed, a piezoelectric vibrating reed, a piezoelectric vibrator, an oscillator, an electronic apparatus, and a radio-controlled timepiece.

2. Description of the Related Art

In recent years, piezoelectric vibrators using crystal or the like as a time of day source or a timing source of a control signal, a reference signal source, or the like are used in cellular phones or portable information terminals. As these kinds of piezoelectric vibrators, various vibrators are provided, but as one of these, a piezoelectric vibrator having a so-called tuning fork type piezoelectric vibrating reed is known. The tuning fork type piezoelectric vibrating reed is a crystal piece having a thin plate shape. The tuning fork type piezoelectric vibrating reed includes a pair of vibrating arm portions that are disposed in parallel in a width direction, and a base portion that integrally fixes base end sides of the pair of vibrating arm portions in the longitudinal direction.

A specific method of forming an external shape of the tuning fork type piezoelectric vibrating reed is as follows.

First, a metallic film, which serves as a metallic mask used later for forming an external shape, is formed on a wafer for forming the piezoelectric vibrating reed through sputtering or the like. Next, a photoresist material is applied to be superimposed in the metallic film so as to form a photoresist film (corresponding to the “masking material film” of the claims of the present application). Subsequently, the photoresist film is patterned by photolithography, and thereby a resist film pattern used for etching the metallic film is formed. Then, the metallic film is etched by using the resist film pattern as a resist mask so as to form a metallic film pattern. Finally, the wafer is etched by using the metallic film pattern as a metal mask. In this manner, the wafer at an area other than an area protected by the metallic film pattern is selectively removed and thereby the external shape of the piezoelectric vibrating reed is formed.

In the above-described process of forming the external shape of the piezoelectric vibrating reed, it is necessary to apply the photoresist material on a surface of the wafer so as to realize a uniform film thickness without variation. The reason is as follows.

For example, when using a negative resist as the photoresist material, in a case where a portion having a large film thickness is present due to variation in the film thickness of the photoresist film, even when being exposed, the photoresist material is not cured sufficiently and is dissolved at the time of development. Therefore, a surface defect occurs in the resist film pattern that is formed by the photoresist film. When the metallic film is etched by using the resist film pattern having the surface defect as the resist mask, the metallic film in a portion corresponding to the surface defect is etched, such that the surface defect is transferred to the metallic film pattern. In addition, when the wafer is etched using the metallic film pattern to which the surface defect is transferred as the metal mask, the wafer at a portion corresponding to the surface defect is etched, and therefore the surface defect is transferred to the piezoelectric vibrating reed formed in the wafer.

That is, the variation of the photoresist film applied onto the surface of the wafer serves as a surface defect of a mask formed of the photoresist film, and therefore this may cause failure at the time of forming the external shape of the piezoelectric vibrating reed. Therefore, it is necessary to apply the photoresist material on the surface of the wafer so that the film thickness of the photoresist film becomes uniform without variation in the film thickness.

As a method of forming the photoresist film on the surface of the wafer, a spin coat method using a spin chuck is known (for example, refer to JP-A-11-150056).

According to JP-A-11-150056, a wafer and a spin chuck rotate in a high speed while the center portion of the wafer is suctioned in a negative pressure by the spin chuck, and a droplet of a photoresist material is dropped onto an upper surface (corresponding to “a first surface” in the claims of the present application) of the wafer. In this manner, the photoresist material spreads in a thin film state by centrifugal force, and thereby a photoresist film is formed on the upper surface of the wafer.

Here, when the spin chuck and the wafer rotate at a high speed, a peripheral surface of the wafer comes into contact with air, and a turbulent flow of air that flows to the lower side of the wafer is generated. Due to the occurrence of the turbulent flow, mist from the photoresist material, dust in the atmosphere, or the like (hereinafter, referred to as “floating matter”), which is generated when the photoresist material is ejected, and when the photoresist material spreads in a thin film state, flows to the lower side of the wafer and therefore there is a concern in that the floating matter may adhere to the lower surface (corresponding to “a second surface” in the claims of the present application) of the wafer that projects from the spin chuck.

FIG. 22 shows an explanatory view of a flow regulating plate 88 having a fin 75 that corresponds to a circular wafer 650.

In general, to radially scatter the photoresist material from the outer periphery of the wafer, a method in which the flow regulating plate 88 is provided below the wafer 650 in the vicinity of the spin chuck 70 is disclosed. Fins 75 that are concentric with the wafer 650 are integrally formed on an upper surface 88a of the flow regulating plate 88 at an inner side of the wafer 650 in the radial direction in relation to an outer edge of the wafer 650 so as to suppress inflow of floating matter to the lower side of the wafer 650 due to the turbulent flow F. The fin 75 serves as a wall to form a residue of the turbulent flow F flowing from the outer side to the inner side in the radial direction, and suppresses the inflow of floating matter, which is transferred by the turbulent flow F, to the lower side of the wafer 650. Therefore, the adhesion of floating matter onto the lower surface of the wafer 650 is suppressed, and the photoresist film is formed uniformly without variation in the film thickness.

### SUMMARY OF THE INVENTION

However, the above-described method is effective to manufacture general semiconductor devices, but there are the following problems in regard to the formation of the external shape of the piezoelectric vibrating reed.

In the manufacturing of the semiconductor devices, a common circular wafer is used, such that when a flow regulating plate having a fin at an inner side in a radial direction in relation to an outer edge of the wafer is used, it is possible to suppress the inflow of floating matter to a lower side of the wafer due to a turbulent flow, over substantially the entire periphery of the wafer.

Contrary to this, in the forming of the external shape of the piezoelectric vibrating reed, a square wafer, which is obtained by slicing a raw ore of a common piezoelectric material, is used, such that even when the flow regulating plate having the above-described fin is used, it is difficult to effectively suppress the inflow of floating matter to the lower side of the square wafer due to the turbulent flow. The reasons are as follows.

In regard to the square wafer, a distance from the rotation center to an outer edge of the square wafer is not constant over the entire outer edge. For example, the distance from the rotation center of the spin chuck to the outer edge at a corner portion of the square wafer, and the distance from the rotation center of the spin chuck to the outer edge at the center of a lateral side of the square wafer are different from each other. Therefore, in the flow regulating plate including the fin having the same distance from the rotation center over the entire periphery, it is difficult to suppress concurrently the inflow of the turbulent flow to a lower side of the corner portion of the square wafer and the inflow of the turbulent flow to a lower side of the lateral side of the square wafer.

In addition, in the manufacturing of the semiconductor device, since only an upper surface of the wafer is commonly used, the photoresist film is formed only on the upper surface of the wafer, and the photoresist film is not formed on the lower surface of the wafer. Therefore, when floating matter adheres to the lower surface, the floating matter may be removed by a back rinsing.

Contrary to this, in the forming of the external shape of the piezoelectric vibrating reed, since the entirety of the wafer is commonly used, the photoresist film is formed on the upper and lower surfaces of the wafer. Here, when the photoresist film is formed on the upper surface of the wafer in a state where the film formation on the lower surface of the wafer is completed, in a case where floating matter adheres to the photoresist film on the lower surface, variation in the film thickness occurs immediately.

Therefore, an object of the invention is to provide a method of manufacturing a piezoelectric vibrating reed and an apparatus for manufacturing a piezoelectric vibrating reed which are capable of suppressing variation in the film thickness at the time of forming a masking material film on a square wafer, a piezoelectric vibrating reed, a piezoelectric vibrator including this piezoelectric vibrating reed, an oscillator, an electronic apparatus, and a radio-controlled timepiece.

To solve the above-described problems, according to an aspect of the invention, there is provided a method of manufacturing a piezoelectric vibrating reed. The method is a method of manufacturing a piezoelectric vibrating reed from a square wafer. The method includes forming a masking material film, which serves as a mask at the time of forming the external shape of the piezoelectric vibrating reed, on a first surface of the square wafer through a spin coating method. In the forming of a masking material film, the square wafer is maintained on an upper surface of a wafer maintaining portion of a spin chuck while a second surface of the square wafer faces downward, a flow regulating plate projecting to an outer side in relation to an outer edge of the square wafer is disposed at a lower side of the wafer maintaining portion of the flow regulating plate, the square wafer is made to rotate with a central axis of the wafer maintaining portion given as a rotation center, a plurality of groove portions, which are concentric with each other with the rotation center given as the center, and a plurality of wall portions, which are adjacent to each other in a radial direction of the respective groove portions, are formed in the upper surface of the flow regulating plate, among the plurality of groove portions, the diameter of the outer side surface of a first groove portion is set to be smaller than the longest distance from the rotation center to the outer edge of the square wafer, and is set to be larger than the shortest distance from the rotation center to the outer edge of the square wafer, and among the plurality of groove portions, the diameter of the outer side surface of a second groove portion is set to be smaller than the shortest distance from the rotation center to the outer edge of the square wafer.

According to this aspect, since the plurality of groove portions are formed in the upper surface of the flow regulating plate, the turbulent flow flowing from the outer side to the inner side in the radial direction under the square wafer may be trapped inside the groove portions to form a residue therein. Therefore, it is possible to suppress the inflow of the turbulent flow to an area located at the inner side in the radial direction in relation to the groove portions.

In addition, among the plurality of groove portions, the diameter of the outer side surface of the first groove portion is set to be smaller than the longest distance from the rotation center to the outer edge of the square wafer, and is set to be larger than the shortest distance from the rotation center to the outer edge of the square wafer. Therefore, it is possible to suppress the inflow of the turbulent flow to the inner side area in the radial direction in relation to the first groove portion, under the square wafer, which is the inner side in the radial direction in relation to the outer edge having the longest distance from the rotation center.

In addition, among the plurality of groove portions, the diameter of the outer side surface of the second groove portion is set to be smaller than the shortest distance from the rotation center to the outer edge of the square wafer. Therefore, it is possible to suppress the inflow of the turbulent flow to the inner side area in the radial direction in relation to the second groove portion, under the square wafer, which is the inner side in the radial direction in relation to the outer edge having the shortest distance from the rotation center.

When the first and second groove portions are formed in this manner, it is possible to suppress the inflow of the turbulent flow within a wide range over substantially the entire periphery of the square wafer. Therefore, it is possible to suppress the inflow of floating matter, which is transported due to the turbulent flow, to the lower side of the square wafer, and adhesion of floating matter to the second surface of the square wafer. As a result, the variation in the film thickness at the time of forming a masking material film on the square wafer is suppressed, and thereby it is possible to suppress the occurrence of defects at the time of forming the external shape of the piezoelectric vibration reed.

In addition, a concave portion may be formed on the upper surface of the flow regulating plate from the outer side of the first groove portion to the outer periphery of the flow regulating plate in the radial direction over the entire periphery of the flow regulating plate.

According to this configuration, the concave portion is formed from the outer side of the first groove portion to the outer periphery of the flow regulating plate in the radial direction along a peripheral direction of the first groove portion over the entire periphery thereof, such that it is possible to form a side wall surface that faces the outer side of the first groove portion in the radial direction. Therefore, floating matter may adhere to the side wall surface, such that it is possible to further suppress the inflow of the floating matter, which is transported due to the turbulent flow, to the lower side of the square wafer, and adhesion of floating matter to the second surface of the square wafer.

In addition, in the forming of a masking material film, airflow may be generated radially from the inner side to the outer side in the radial direction between the upper surface of the flow regulating plate and the second surface of the square wafer.

According to this configuration, since the airflow is generated radially from the inner side to the outer side in the radial direction between the upper surface of the flow regulating plate and the second surface of the square wafer, even when the turbulent flow is apt to flow to the lower side of the square wafer, this turbulent flow may be pushed back, and thereby it is possible to suppress the inflow of the turbulent flow. Therefore, it is possible to suppress the entering of floating matter from the outer side to the inner side in the radial direction under the square wafer. Therefore, it is possible to further suppress the inflow of floating matter, which are transported due to the turbulent flow, to the lower side of the square wafer, and adhesion of the floating matter to the second surface of the square wafer.

In addition, the height of the plurality of the wall portions may gradually enlarge as they go from the inner side to the outer side in the radial direction.

According to this configuration, since as they go from the inner side to the outer side in the radial direction, the height of the wall portions may gradually enlarge, as they go toward the outer side in the radial direction, the gap between the second surface of the square wafer and the wall portion may become narrow. Therefore, the velocity of the airflow, which is generated radially from the inner side to the outer side in the radial direction, may increase at the outer side in the radial direction. Therefore, even when the turbulent flow is apt to flow to the lower side of the square wafer, the turbulent flow is pushed back, such that it is possible to suppress the inflow of the turbulent flow. Therefore, it is possible to further suppress the inflow of floating matter, which is transported due to the turbulent flow, to the lower side of the square wafer, and adhesion of the floating matter to the second surface of the square wafer.

In addition, the upper end surfaces of the respective wall portions may be formed of inclined surfaces that become high as they go from the inner side to the outer side in the radial direction.

According to this configuration, since the upper end surfaces of the respective wall portions are formed of inclined surfaces that become high as they go from the inner side to the outer side in the radial direction, as they go toward the outer side in the radial direction, the gap between the second surface of the square wafer and the wall portion becomes narrow. Therefore, the velocity of the airflow, which is generated radially from the inner side to the outer side in the radial direction, may be increased at the outer side in the radial direction. Therefore, even when the turbulent flow is apt to flow to the lower side of the square wafer, the turbulent flow is pushed back, such that it is possible to suppress the inflow of the turbulent flow. As a result, it is possible to further suppress the inflow of floating matter, which is transported due to the turbulent flow, to the lower side of the square wafer, and adhesion of the floating matter to the second surface of the square wafer.

In addition, according to another aspect of the invention, there is provided an apparatus for manufacturing a piezoelectric vibrating reed. The apparatus is an apparatus for manufacturing a piezoelectric vibrating reed, which is used when forming a masking material film on a first surface of a square wafer through a spin coating method at the time of forming the external shape of the piezoelectric vibrating reed. The apparatus includes a spin chuck that maintains the square wafer on an upper surface of a wafer maintaining portion while a second surface of the square wafer faces a lower side, and that rotates the square wafer with a central axis of the wafer maintaining portion given as a rotation center; and a flow regulating plate that projects to an outer side in relation to an outer edge of the square wafer and that is disposed at a lower side of the wafer maintaining portion. A plurality of groove portions, which are concentric with each other with the rotation center given as the center, and a plurality of wall portions, which are adjacent to each other in a radial direction of the respective groove portions, are formed in the upper surface of the flow regulating plate, among the plurality of groove portions, the diameter of the outer side surface of a first groove portion in the radial direction is set to be smaller than the longest distance from the rotation center to the outer edge of the square wafer, and is set to be larger than the shortest distance from the rotation center to the outer edge of the square wafer, and among the plurality of groove portions, the diameter of the outer side surface of a second groove portion, which is formed in an inner side in relation to the first groove portion, is set to be smaller than the shortest distance from the rotation center to the outer edge of the square wafer.

According to this aspect, since the plurality of groove portions are formed in the upper surface of the flow regulating plate, the turbulent flow flowing from the outer side to the inner side in the radial direction under the square wafer may be trapped inside the groove portions to form a residue therein. Therefore, it is possible to suppress the inflow of the turbulent flow to an area located at the inner side in the radial direction in relation to the groove portions.

In addition, among the plurality of groove portions, the diameter of the outer side surface of the first groove portion is set to be smaller than the longest distance from the rotation center to the outer edge of the square wafer, and is set to be larger than the shortest distance from the rotation center to the outer edge of the square wafer. Therefore, it is possible to suppress the inflow of the turbulent flow to the inner side area in the radial direction in relation to the first groove portion, under the square wafer, which is the inner side in the radial direction in relation to the outer edge having the longest distance from the rotation center.

In addition, among the plurality of groove portions, the diameter of the outer side surface of the second groove portion is set to be smaller than the shortest distance from the rotation center to the outer edge of the square wafer. Therefore, it is possible to suppress the inflow of the turbulent flow to the inner side area in the radial direction in relation to the second groove portion, under the square wafer, which is the inner side in the radial direction in relation to the outer edge having the shortest distance from the rotation center.

When the first and second groove portions are formed in this manner, it is possible to suppress the inflow of the turbulent flow within a wide range over substantially the entire periphery of the square wafer. Therefore, it is possible to suppress the inflow of floating matter, which is transported due to the turbulent flow, to the lower side of the square wafer, and adhesion of floating matter to the second surface of the square wafer. As a result, the variation in the film thickness at the time of forming a masking material film on the square wafer is suppressed, and thereby it is possible to suppress the occurrence of defects at the time of forming the external shape of the piezoelectric vibration reed.

In addition, according to still another aspect of the invention, there is provided a piezoelectric vibrating reed that is manufactured by the above-described manufacturing method.

According to this aspect, variation in the film thickness of a masking material film is suppressed by the manufacturing method described above, such that it is possible to form the piezoelectric vibrating reeds with good accuracy. Therefore, the number of piezoelectric vibrating reeds that are discarded due to failure in the external shape decreases, such that the manufacturing cost of the piezoelectric vibrating reeds may be lowered.

In addition, according to still another aspect of the invention, there is provided a piezoelectric vibrator including the piezoelectric vibrating reed manufactured by the above-described manufacturing method.

According to this aspect, an inexpensive piezoelectric vibrating reed is included, such that it is possible to obtain an inexpensive piezoelectric vibrator.

In addition, according to still another aspect of the invention, there is provided an oscillator in which the above-described piezoelectric vibrator is electrically connected to an integrated circuit as an oscillating element.

In addition, according to still another aspect of the invention, there is provided an electronic apparatus in which the above-described piezoelectric vibrator is electrically connected to a time counting unit.

In addition, according to still another aspect of the invention, there is provided a radio-controlled timepiece in which the above-described piezoelectric vibrator is electrically connected to a filter unit.

According to the oscillator, the electronic apparatus, and the radio-controlled timepiece of the aspects, an inexpensive piezoelectric vibrator is included, such that it is possible to obtain an inexpensive oscillator, electronic apparatus, and radio-controlled timepiece.

According to the aspects of the invention, since the plurality of groove portions are formed in the upper surface of the flow regulating plate, the turbulent flow flowing from the outer side to the inner side in the radial direction under the square wafer may be trapped inside the groove portions to form a residue therein. Therefore, it is possible to suppress the inflow of the turbulent flow to an area located at the inner side in the radial direction in relation to the groove portions.

In addition, among the plurality of groove portions, the diameter of the outer side surface of the first groove portion is set to be smaller than the longest distance from the rotation center to the outer edge of the square wafer, and is set to be larger than the shortest distance from the rotation center to the outer edge of the square wafer. Therefore, it is possible to suppress the inflow of the turbulent flow to the inner side area in the radial direction in relation to the first groove portion, under the square wafer, which is the inner side in the radial direction in relation to the outer edge having the longest distance from the rotation center.

In addition, among the plurality of groove portions, the diameter of the outer side surface of the second groove portion is set to be smaller than the shortest distance from the rotation center to the outer edge of the square wafer. Therefore, it is possible to suppress the inflow of the turbulent flow to the inner side area in the radial direction in relation to the second groove portion, under the square wafer, which is the inner side in the radial direction in relation to the outer edge having the shortest distance from the rotation center.

When the first and second groove portions are formed in this manner, it is possible to suppress the inflow of the turbulent flow within a wide range over substantially the entire periphery of the square wafer. Therefore, it is possible to suppress the inflow of floating matter, which is transported due to the turbulent flow, to the lower side of the square wafer, and adhesion of the floating matter to the second surface of the square wafer. As a result, the variation in the film thickness at the time of forming a masking material film on the square wafer is suppressed, and thereby it is possible to suppress the occurrence of defects at the time of forming the external shape of the piezoelectric vibration reed.

### BRIEF DESCRIPTION OF THE DRAWINGS

FIG. 1 is a plan view of a piezoelectric vibrating reed;

FIG. 2 is a cross-sectional view taken along a line A-A in FIG. 1;

FIG. 3 is a flowchart of a manufacturing process of the piezoelectric vibrating reed;

FIG. 4 is an explanatory view of a square wafer;

FIG. 5 is a side cross-sectional view of a film forming apparatus;

FIG. 6 is a plan view of the film forming apparatus;

FIG. 7 is a functional explanatory view of a groove portion of a flow regulating plate;

FIG. 8 is an explanatory view of a photoresist film forming process;

FIG. 9 is an explanatory view of a resist film pattern forming process;

FIG. 10 is an explanatory view of a metallic film pattern forming process;

FIG. 11 is an explanatory view of a square wafer etching process;

FIG. 12 is an explanatory view of the square wafer after being etched;

FIG. 13 is an explanatory view of a flow regulating plate according to a first modification of this embodiment;

FIG. 14 is an explanatory view of a flow regulating plate according to a second modification of this embodiment;

FIG. 15 is an external perspective view of a piezoelectric vibrator;

FIG. 16 is an internal configuration diagram of the piezoelectric vibrator, in which a state where a lid substrate is detached is shown in a plan view;

FIG. 17 is a cross-sectional view taken along a B-B line in FIG. 16;

FIG. 18 is an exploded perspective view of the piezoelectric vibrator shown in FIG. 15;

FIG. 19 is a configuration diagram illustrating an embodiment of an oscillator;

FIG. 20 is a configuration diagram illustrating an embodiment of an electronic apparatus;

FIG. 21 is a configuration diagram illustrating an embodiment of a radio-controlled timepiece; and

FIG. 22 is an explanatory view of a flow regulating plate having a fin corresponding to a circular wafer.

### DETAILED DESCRIPTION OF THE PREFERRED EMBODIMENTS

### Piezoelectric Vibrating Reed

First, a piezoelectric vibrating reed according to an embodiment of the invention will be described with reference to accompanying drawings.

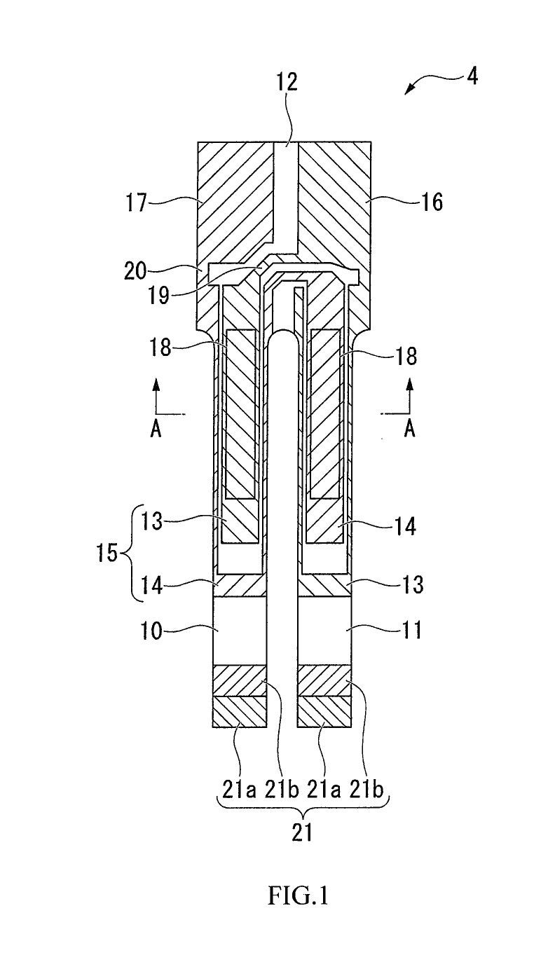

FIG. 1 shows a plan view of a piezoelectric vibrating reed 4.

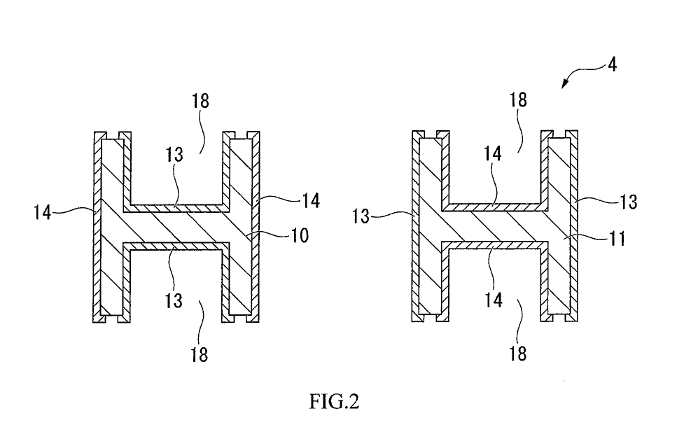

FIG. 2 shows a cross-sectional view taken along a line A-A in FIG. 1.

As shown in FIG. 1, the piezoelectric vibrating reed 4 of this embodiment is a tuning fork type vibrating reed formed of a square crystal wafer (hereinafter, referred to as a “square wafer”), and vibrates when a predetermined voltage is applied thereto. The piezoelectric vibrating reed 4 includes a pair of vibrating arm portions 10 and 11 that are disposed in parallel with each other, a base portion 12 that integrally fixes base end sides of the pair of vibrating arm portions 10 and 11, and vibrating arm groove portions 18 that are formed at both principal surfaces of the pair of vibrating arm portions 10 and 11. The vibrating arm groove portions 18 are formed along a longitudinal direction of the vibrating arm portions 10 and 11 to a position located at a substantially intermediate portion from the base end sides of the vibrating arm portions 10 and 11.

The piezoelectric vibrating reed 4 includes an excitation electrode 15 having a first excitation electrode 13 and a second excitation electrode 14 that are formed on external surfaces of the pair of vibrating arm portions 10 and 11 and that vibrate the pair of vibrating arm portions 10 and 11, mounting electrodes 16 and 17 that are formed on the base portion 12 to mount the piezoelectric vibrating reed 4 in a package, and lead-out electrodes 19 and 20 that electrically connect the first and second excitation electrodes 13 and 14, and the mounting electrodes 16 and 17 to each other.

The excitation electrode 15 and the lead-out electrodes 19 and 20 are formed of a single layer film using chrome that is the same material as that of underlying layers of the mounting electrodes 16 and 17 described later. Therefore, it is possible to simultaneously form the underlying layers of the mounting electrodes 16 and 17, and the excitation electrode 15 and the lead-out electrodes 19 and 20. However, it is not limited to this case, and the excitation electrode 15, and the lead-out electrodes 19 and 20 may be formed of, for example, nickel, aluminum, titanium, or the like.

The excitation electrode 15 is an electrode that vibrates the pair of vibrating arm portions 10 and 11 with a predetermined resonance frequency in a direction to be close to each other or in a direction to be distant from each other. The first excitation electrode 13 and the second excitation electrode 14, which make up the excitation electrode 15, are patterned in a state where these are electrically separated, respectively, and are formed on the external surfaces of the pair of vibrating arm portions 10 and 11 (refer to FIG. 2). In addition, the first excitation electrode 13 and the second excitation electrode 14 are electrically connected to the mounting electrodes 16 and 17 described later through the lead-out electrodes 19 and 20, respectively, on both the principal surfaces of the base portion 12.

The mounting electrodes 16 and 17 are laminated films of chrome and gold, and are formed by forming a chrome film having an excellent adhesion property with crystal as an underlying layer, and forming a gold thin film as a top layer on a surface of the chrome film. However, it is not limited to this case, and the mounting electrodes 16 and 17 may be formed, for example, by forming chrome and nichrome films as underlying layers and by further forming the gold thin film as the top layer on a surface of the underlying layers.

Heavy metal films 21 are formed at leading ends of the pair of vibrating arm portions 10 and 11 for performing adjustment (frequency adjustment) such that the pair of vibrating arm portions 10 and 11 vibrate within a predetermined frequency range. The heavy metal films 21 are classified into a rough adjustment film 21a that is used at the time of roughly adjusting a frequency, and a minute adjustment film 21b that is used at the time of minutely adjusting a frequency. The rough adjustment film 21a and the minute adjustment film 21b perform the frequency adjustment, and thereby allow the frequency of the pair of vibrating arm portions 10 and 11 to be put within a range of a nominal frequency of a device.

### Method of Manufacturing Piezoelectric Vibrating Reed

Next, a manufacturing process of the above-described piezoelectric vibrating reed 4 will be described with reference a flowchart.

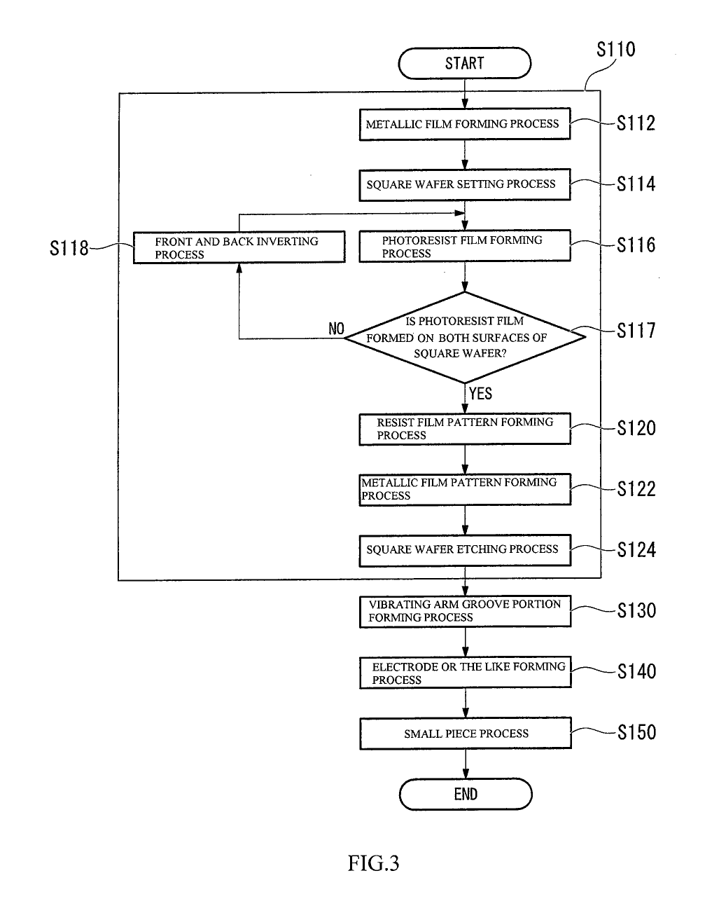

FIG. 3 shows a flowchart of a manufacturing process of the piezoelectric vibrating reed 4.

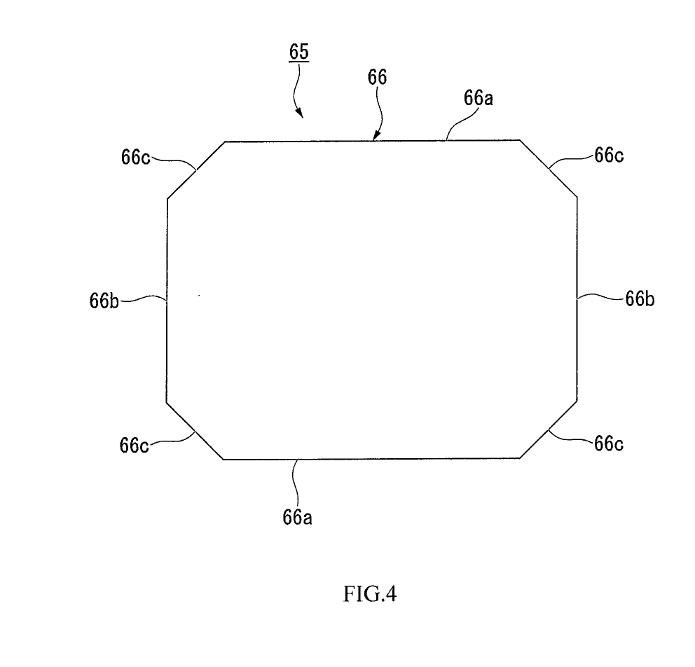

The manufacturing process of the piezoelectric vibrating reed 4 includes an external shape forming process S110 to form an external shape of the piezoelectric vibrating reed 4 on a square wafer 65 (refer to FIG. 4), a vibrating arm groove portion forming process S130 to form a concave portion serving as a vibrating arm groove portion 18 of the piezoelectric vibrating reed 4 (refer to FIG. 2), an electrode or the like forming process S140 to form respective electrodes, and a small piece process S150 to cut the piezoelectric vibrating reed 4 from the square wafer 65. Hereinafter, the details of respective processes will be described.

### External Shape Forming Process S110 and Square Wafer

FIG. 4 shows an explanatory view of the square wafer 65.

The piezoelectric vibrating reed 4 according to this embodiment is made from the square wafer 65. The square wafer 65 is formed by slicing a raw ore of a piezoelectric material such as crystal having a rectangular parallelepiped shape into a flat plate to have a substantially rectangular shape in a plan view. An outer edge 66 of the square wafer 65 includes long sides 66a, short sides 66b, and oblique sides 66c formed by chamfering corners of the long sides 66a and the short sides 66b.

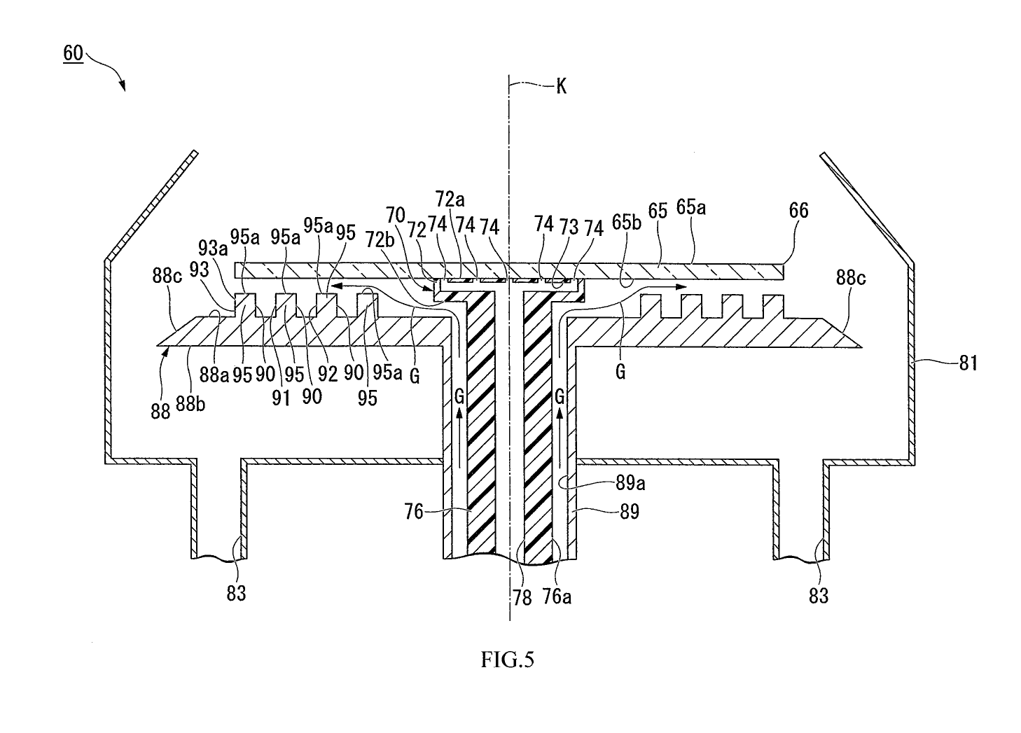

The external shape forming process S110 includes a metallic film forming process S112 to form a metallic film on a surface of the square wafer 65, a square wafer setting process S114 to set the square wafer 65 to a spin chuck 70 (refer to FIG. 5) described later, and a photoresist film forming process S116 (corresponding to a masking material film forming process in the claims of the present application) to form a photoresist material film (corresponding to a masking material film in the claims of the present application) on the square wafer 65.

In addition, the external shape forming process S110 further includes a resist film pattern forming process S120 to form a resist film pattern from a photoresist film by photolithography technology, a metallic film pattern forming process S122 to form a metallic film pattern by etching the metallic film using the resist film pattern as a mask, and a square wafer etching process S124 to etch the square wafer 65 using the metallic film pattern as a mask. In addition, in the following description, in both surfaces of the square wafer 65, a surface that is disposed at an upper side in the first square wafer setting process S114 is set as a first surface 65a, and a surface that is disposed at a lower side is set as a second surface 65b.

### Metallic Film Forming Process S112

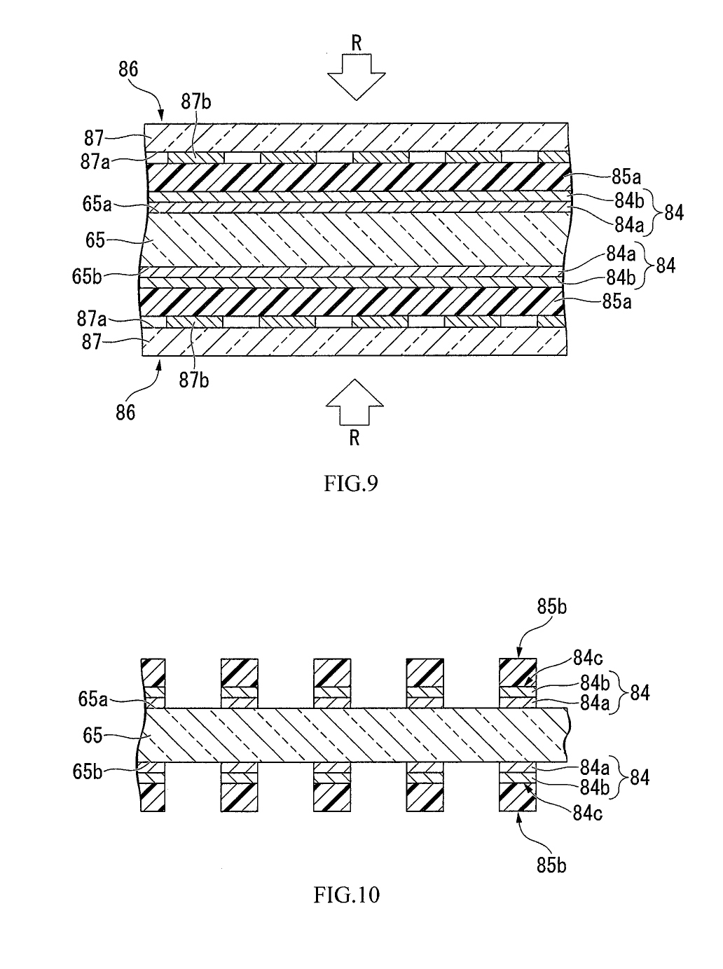

First, in the metallic film forming process S112, a metallic film 84 (refer to FIG. 9) is formed on the square wafer 65 that is polished and thereby is finished with high accuracy to have a predetermined thickness. The metallic film 84 is a laminated film of, for example, an underlying film 84a formed of chrome (refer to FIG. 9), and a protective film 84b formed of gold (refer to FIG. 9), and the underlying film 84a and the protective film 84b are formed through a sputtering method or a vapor deposition method, respectively. In addition, the metallic film pattern formed in the metallic film forming process S112 serves as a metallic mask at the time of etching the square wafer 65 in the square wafer etching process S124 and the vibrating arm groove portion forming process S130.

### Square Wafer Setting Process S114 and Film Forming Apparatus

Next, the square wafer setting process S114 is performed to set the square wafer 65 in a spin chuck 70 making up a film forming apparatus 60.

FIG. 5 is a side cross-sectional view of the film forming apparatus 60.

Hereinafter, first, the film forming apparatus 60 is described, and then the square wafer setting process S114 is described. In addition, in FIG. 5, the metallic film 84 formed on the surface of the square wafer 65 is omitted for easy understanding of the drawing. In addition, the drawing is exaggeratedly drawn in consideration of a width and a depth of a groove portion 90 (a first groove portion 91 and a second groove portion 92) described later, which is formed on a flow regulating plate 88.

The film forming apparatus 60 includes the spin chuck 70 that maintains the square wafer 65 in a wafer maintaining portion 72 and rotates the square wafer 65, the flow regulating plate 88 that is disposed at a lower side of the wafer maintaining portion 72 of the spin chuck 70, and coater cup 81 that covers the external side of the spin chuck 70 and the flow regulating plate 88.

### Spin Chuck

As shown in FIG. 5, the spin chuck 70 includes the wafer maintaining portion 72 that maintains the square wafer 65, and a column portion 76 that is provided to extend from the wafer maintaining portion 72 in a downward direction along a rotation center K of the spin chuck 70, and supports the wafer maintaining portion 72. The wafer maintaining portion 72 and the column portion 76 is formed of, for example, a resin, metal, or the like.

The wafer maintaining portion 72 is a plate-shaped member having a substantially circular shape in a plan view. The diameter of the wafer maintaining portion 72 is set to be smaller than the distance between the long sides 66a of the square wafer 65. Since the wafer maintaining portion 72 is formed in this manner, when the square wafer 65 is placed on the wafer maintaining portion 72, the entirety of an upper surface 72a of the wafer maintaining portion 72 may be brought into contact with the second surface 65b of the square wafer 65.

The wafer maintaining portion 72 has a plurality of suction holes 74 in the upper surface 72a over the entire surface thereof. The suction holes 74 are connected to a vacuum pump (not shown) through a suction passage 73 formed inside the wafer maintaining portion 72 and a suction passage 78 formed in a column portion 76 described later. When being evacuated by the vacuum pump, the square wafer 65 is suctioned by a negative pressure onto the wafer maintaining portion 72, and is maintained on the upper surface 72a of the wafer maintaining portion 72.

The column portion 76 is formed on a lower surface 72b of wafer maintaining portion 72 so as to extend along the rotation center K in a downward direction.

The column portion 76 is a hollow, columnar member, and is formed integrally with the wafer maintaining portion 72 in order for the central axis to be substantially coincident with the central axis of the wafer maintaining portion 72.

The suction passage 78 is formed inside the column portion 76, and communicates with the vacuum pump (not shown). The suction passage 78 communicates with the suction passage 73 and suction holes 74 formed in the wafer maintaining portion 72.

The column portion 76 is connected to a motor (not shown). When the motor is driven to rotate, the entirety of the spin chuck 70 rotates around the rotation center K. In addition, the flow regulating plate 88 described later is formed to be spaced from the spin chuck 70, and therefore the flow regulating plate does not rotate.

### Coater Cup

The coater cup 81 is formed to surround sides and bottoms of the spin chuck 70 and the flow regulating plate 88. Exhaust ports 83 that communicate with the suction pump (not shown) are formed under the coater cup 81. Therefore, when being suctioned by the suction pump, the inside of the coater cup 81 becomes a negative pressure state. Mist from the photoresist material 85, which is scattered from the surface of the square wafer 65, is discharged to the outside of the coater cup 81 from the exhaust ports 83.

### Flow Regulating Plate

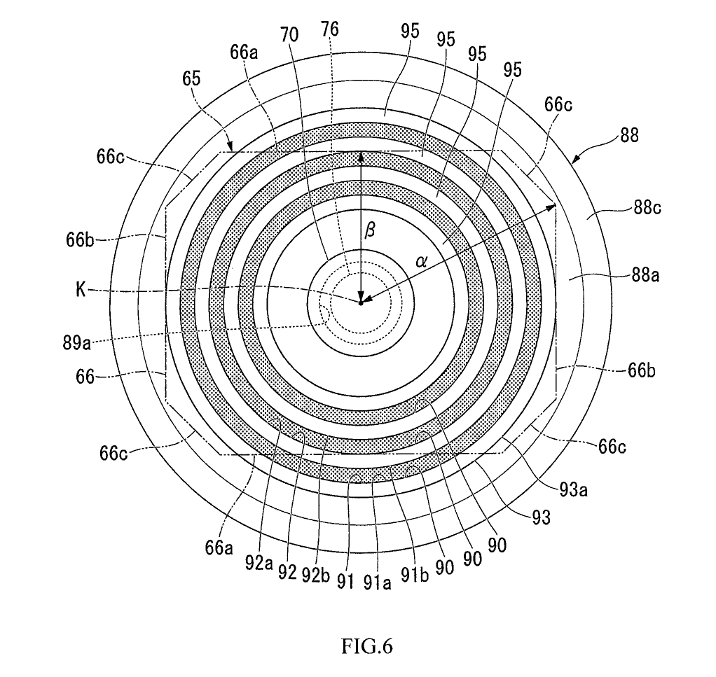

FIG. 6 is a plan view of the film forming apparatus 60. In addition, in FIG. 6, for easy understanding of the drawing, the square wafer 65 is shown by a two-dotted line. In addition, the coater cup 81 described later is omitted. In addition, in FIG. 6, for easy understanding of the drawing, groove portions 90 are shown with being hatched. In addition, in the following description, “radial direction” means a radial direction of the wafer maintaining portion 72 and the groove portions 90 formed in the upper surface 88a of the flow regulating plate 88.

As shown in FIG. 6, the flow regulating plate 88 is a member having a substantially circular shape, and is formed of, for example, metal such as aluminum. The flow regulating plate 88 has a diameter larger than the longest distance from the rotation center K to the outer edge 66 of the square wafer 65, and projects to the outside in relation to the outer edge 66 of the square wafer 65.

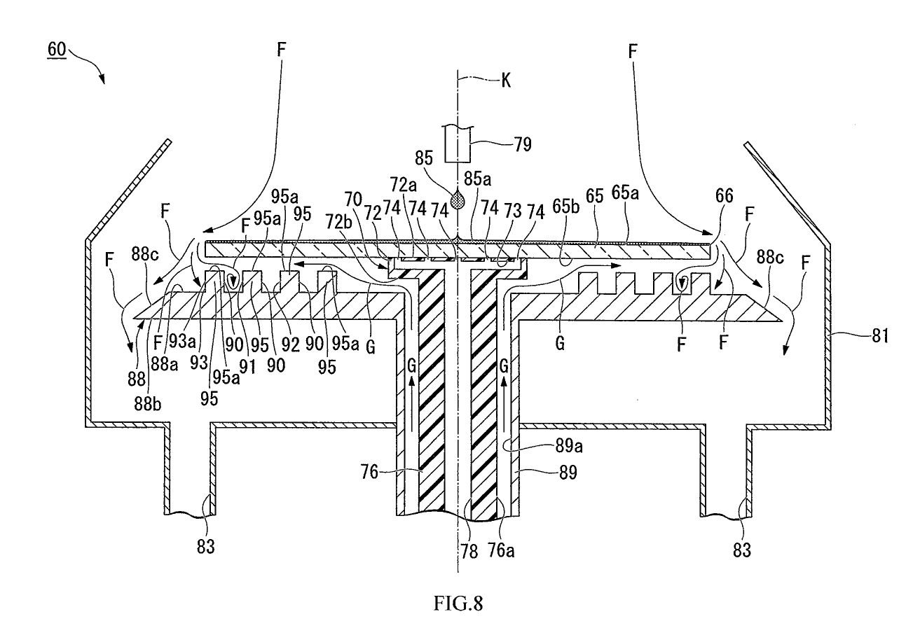

As shown in FIG. 5, the flow regulating plate 88 is disposed under the wafer maintaining portion 72 of the spin chuck 70. An outer peripheral edge portion of the flow regulating plate 88 in the radial direction is configured as an inclined surface 88c that is inclined in a downward direction. In the photoresist film forming process S116 described later, floating matter such as mist from the photoresist material 85 (refer to FIG. 8), which is generated due to the high speed rotation of the square wafer 65, and dust are guided to a lower side of the flow regulating plate 88 along the inclined surface 88c. The transported floating matter is discharged to the outside of the film forming apparatus 60 from the exhaust ports 83 provided under the coater cup 81 described later.

A plurality of (three in this embodiment) groove portions 90, which are concentric with each other with the rotation center K given as the center, is formed in the upper surface 88a of the flow regulating plate 88.

Each of the groove portions 90 has an opening on the upper surface 88a of the flow regulating plate 88, a depth of the groove portion 90 is set to, for example, substantially 1 to 3 mm, and a width thereof is set to, for example, substantially 1 to 3 mm. The respective groove portions 90 may be formed to have the same depth and width as each other, or may be formed to have depths and widths different from each other. The depth and width of each of the groove portions 90 are set depending on an air volume of a turbulent flow F, or the like. In this embodiment, the depths and widths of the respective groove portions 90 are set to be substantially the same as each other.

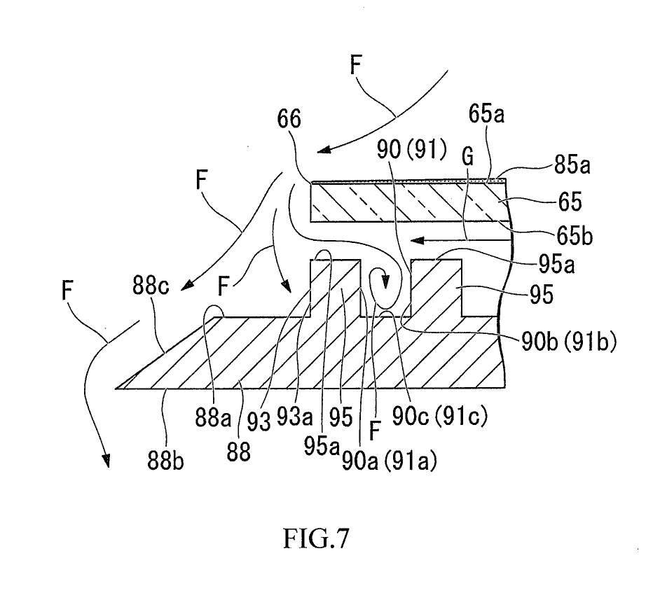

FIG. 7 shows a functional explanatory view of the groove portion 90 of the flow regulating plate 88.

As shown in FIG. 7, as the turbulent flow F that is generated due to the high speed rotation of the square wafer 65 flows from the outer side to the inner side in the radial direction at a lower side of the square wafer 65, the turbulent flow F collides with the inner side surface 90b of the groove portion 90, moves along a lower surface 90c and an outer side surface 90a, and forms a residue inside the groove portion 90 while being swirled. In this manner, the turbulent flow F is trapped by the groove portion 90, such that it is possible to suppress inflow of the turbulent flow F to the second surface 65b of the square wafer 65.

As shown in FIG. 6, among the plurality of groove portions 90, a diameter of the outer side surface 91a of the first groove portion 91 is set to be smaller than the longest distance α from the rotation center K to the outer edge 66 of the square wafer 65. In this embodiment, the distance between the rotation center K and a short side 66b side end of the oblique side 66c becomes the longest distance α. Therefore, the outer side surface 91a of the first groove portion 91 is formed at the inner side in the radial direction in relation to the short side 66b side end of the oblique side 66c.

In addition, the diameter of the outer side surface 91a of the first groove portion 91 is set to be larger than the shortest distance β from the rotation center K to the outer edge 66 of the square wafer 65. In this embodiment, the distance from the rotation center K to the center portion of the long side 66a becomes the shortest distance β. Therefore, the outer side surface 91a of the first groove portion 91 is formed at the outer side in the radial direction in relation to the center portion of the long side 66a.

In addition, among the plurality of groove portions 90, the diameter of the outer side surface 92a of the second groove portion 92 is set to be smaller than the shortest distance β from the rotation center K to the outer edge 66 of the square wafer 65. Therefore, the outer side surface 92a of the second groove portion 92 is formed at the inner side in the radial direction in relation to the center portion of the long side 66a.

In addition, as shown in FIG. 5, a concave portion 93 is formed at an outer side of the first groove portion 91 in the radial direction. The concave portion 93 is formed by notching the outer side of the first groove portion 91 of the flow regulating plate 88 in the radial direction along the peripheral direction of the first groove portion 91 over the entire periphery thereof with a substantially L shape in a side cross-sectional view. When the flow regulating plate 88 is notched in this way, a side wall surface 93a that faces the outer side in the radial direction is formed at the outer side of the first groove portion 91 in the radial direction.

As shown in FIG. 6, a plurality of (four in this embodiment) wall portions 95, which are adjacent to each other in the radial direction of the plurality of groove portion 90, is formed in the upper surface 88a of the flow regulating plate 88.

Each of the wall portions 95 is formed to have a height of, for example, substantially 1 to 3 mm, and a width of, for example, substantially 1 to 3 mm. The respective wall portions 95 may be formed to have the same height and width as each other, or may be formed to have heights and widths different from each other. The height and width of each of the wall portions 95 are set depending on the air volume of the turbulent flow F, or the like. In this embodiment, the heights and widths of the respective wall portions 95 are set to be substantially the same as each other. In addition, an upper end surface 95a of the wall portion 95 is horizontally formed so as to be substantially parallel with the second surface 65b of the square wafer 65.

As shown in FIG. 5, a flow regulating plate column portion 89 is formed at substantially the center of the lower surface 88b of the flow regulating plate 88 to extend along the rotation center K in a downward direction.

The flow regulating plate column portion 89 is a hollow member, and the inside of the flow regulating plate column portion 89 is formed of a penetration hole 89a that communicates between the upper surface 88a of the flow regulating plate 88 and the outside.

The penetration hole 89a has a diameter larger than that of the column portion 76 of the spin chuck 70. The column portion 76 is disposed to penetrate through the inside of the penetration hole 89a, and space is formed between the inner circumferential surface 89b of the penetration hole 89a and the outer circumferential surface 76a of the column portion 76. In this embodiment, the penetration hole 89a communicates with means (not shown) for supplying gas. Inert gas such as nitrogen gas or dry air is supplied from the means for supplying gas, and therefore an airflow G flows in the space between the inner circumferential surface 89b of the penetration hole 89a and the outer circumferential surface 76a of the column portion 76 from the lower side to the upper side.

The airflow G moves along the outer circumferential surface 76a of the column portion 76, the lower surface 72b of the wafer maintaining portion 72, and the second surface 65b of the square wafer 65. Therefore, the airflow G is generated radially from the inner side to the outer side in the radial direction between the upper surface 88a of the flow regulating plate 88 and the second surface 65b of the square wafer 65.

### Wafer Setting Process S114

A square wafer setting process S114 is performed to set the square wafer 65 on which a metallic film is formed in the spin chuck 70 of the film forming apparatus 60 configured as described above.

In the square wafer setting process S114, the square wafer 65 is set in the wafer maintaining portion 72 of the spin chuck 70. Specifically, the second lower-side surface 65b of the square wafer 65 and the upper surface 72a of the wafer maintaining portion 72 are brought into contact with each other, and then the square wafer 65 is placed on the upper surface 72a of the wafer maintaining portion 72. A positioning mechanism (not shown) is provided between the second surface 65b of the square wafer 65 and the upper surface 72a of the wafer maintaining portion 72, and the square wafer 65 is placed in such a manner that the center axis of the square wafer 65 is substantially coincident with the rotation center K of the spin chuck 70. Then, the vacuum pump (not shown) performs evacuation, and thereby the second surface 65b of the square wafer 65 is vacuum-suctioned by the wafer maintaining portion 72 and the square wafer 65 is fixed to the wafer maintaining portion 72.

### Photoresist Film Forming Process S116

FIG. 8 shows an explanatory view of the photoresist film forming process S116.

Continuously, as shown in FIG. 8, the photoresist film forming process S116 is performed to form the photoresist film 85a on the square wafer 65 by the application of the photoresist material 85. In addition, the photoresist film forming process S116 is performed in the atmosphere. In addition, the photoresist material 85 that is applied in this embodiment is a so-called negative resist material in which an exposed portion is cured and remains at the time of development.

In the photoresist film forming process S116, the motor (not shown) is driven to rotate, and thereby the spin chuck 70 and the square wafer 65 is made to rotate at a high speed.

In addition, inert gas such as nitrogen gas or dry air is supplied from the means for supplying gas, and therefore the airflow G flows in the space between the inner circumferential surface 89b of the penetration hole 89a and the outer circumferential surface 76a of the column portion 76.

In addition, as shown in FIG. 8, the photoresist material 85 is dropped from a nozzle 79, which is disposed at an upper side of the square wafer 65 along the rotation center K, toward the first surface 65a of the square wafer 65.

When being adhered onto the first surface 65a of the square wafer 65, the dropped photoresist material 85 spreads in a thin film state by centrifugal force from a substantially center of the square wafer 65 to the outer edge 66. Therefore, a photoresist film 85a is formed on the first surface 65a of the square wafer 65.

At this time, the turbulent flow F is generated at the periphery of the square wafer 65 due to the high speed rotation of the square wafer 65. Floating matter such as mist from the photoresist material 85, which is generated when the photoresist material 85 is dropped and when the photoresist material 85 spreads in a thin film state, and dust in the atmosphere are transferred to the lower side of the square wafer 65 due to the turbulent flow F. Therefore, there is a concern in that floating matter may adhere to the second surface 65b of the square wafer 65, and thereby variation may occur in the film thickness of the photoresist film 85a.

However, in this embodiment, the flow regulating plate 88 is disposed under the wafer maintaining portion 72, and the plurality of groove portions 90 is formed in the upper surface 88a of the flow regulating plate 88. Therefore, as shown in FIG. 7, the turbulent flow F flowing from the outer side to the inner side in the radial direction under the square wafer 65 may be trapped inside the groove portions 90 to form a residue therein. As a result, it is possible to suppress the inflow of the turbulent flow F to an area located at the inner side in the radial direction in relation to the groove portions 90.

Here, among the plurality of groove portions 90, the diameter of the outer side surface 91a of the first groove portion 91 is set to be smaller than the longest distance α from the rotation center K to the outer edge 66 of the square wafer 65, and is set to be larger than the shortest distance 13 from the rotation center K to the outer edge 66 of the square wafer 65. When the first groove portion 91 is formed in this manner, it is possible to suppress the inflow of the turbulent flow F to an inner side area in the radial direction in relation to the first groove portion 91, under the square wafer 65, which is an inner side in the radial direction in relation to the short side 66b side end of the oblique side 66c having the longest distance α from the rotation center K.

In addition, the diameter of the outer side surface 92a of the second groove portion 92 is set to be smaller than the shortest distance β from the rotation center K to the outer edge 66 of the square wafer 65. When the second groove portion 92 is formed in this manner, it is possible to suppress the inflow of the turbulent flow F to an inner side area in the radial direction in relation to the second groove portion 92, under the square wafer 65, which is an inner side in the radial direction in relation to the center of the long side 66a.

In this manner, it is possible to suppress the inflow of the turbulent flow F within a wide range over substantially the entire periphery of the square wafer 65 due to the first and second groove portions 91 and 92, such that it is possible to further suppress the inflow of floating matter, which is transported due to the turbulent flow F, to the lower side of the square wafer 65, and adhesion of floating matter to the second surface 65b of the square wafer 65. Therefore, the variation in the film thickness at the time of forming the photoresist film 85a on the square wafer 65 is suppressed, and thereby it is possible to suppress the occurrence of defects at the time of forming the external shape of the piezoelectric vibration reed 4.

In addition, as shown in FIG. 7, a part of the turbulent flow F that is generated by the high speed rotation of the square wafer 65 collides with the side wall surface 93a that is formed at the concave portion 93, under the square wafer 65. Therefore, mist from the photoresist material 85 among the floating matter transported by the turbulent flow F is made to adhere to the side wall surface 93a. Therefore, it is possible to suppress the inflow of floating matter, which is transported due to the turbulent flow F, to the lower side of the square wafer 65, and adhesion of floating matter to the second surface 65b of the square wafer 65.

In addition, the airflow G is generated radially from the inner side to the outer side in the radial direction between the upper surface 88a of the flow regulating plate 88 and the second surface 65b of the square wafer 65. Therefore, the inflow of the turbulent flow F to the lower side of the square wafer 65 from the outer side in the radial direction is pushed back and thereby it is possible to suppress the inflow of the turbulent flow F. Therefore, it is possible to suppress the inflow of floating matter, which is transported due to the turbulent flow F, to the lower side of the square wafer 65, and adhesion of the floating matter to the second surface 65b of the square wafer 65.

### Confirmation of Application Surface S117 and Front and Back Inverting Process S118

In a case where the photoresist film 85a is not formed on the second face 65b of the square wafer 65, which is disposed in the lower side, after the photoresist film 85a is formed on the first surface 65a of the square wafer 65 (S117), the front and the back of the first surface 65a and the second surface 65b of the square wafer 65 are inverted and then the photoresist film forming process S116 is performed again with respect to the second surface 65b of the square wafer 65.

In the photoresist film forming process S116 that is performed again, as described above, it is possible to suppress the inflow of the turbulent flow F within a wide range over substantially the entire periphery of the square wafer 65 due to the first groove portion 91 and the second groove portion 92, such that adherence of floating matter onto the first surface 65a of the square wafer 65 disposed in the lower side may be suppressed. Therefore, it is possible to suppress the variation in the film thickness at the time of forming the photoresist film 85a.

In this manner, the photoresist film 85a is formed on the first and second surfaces 65a and 65b of the square wafer 65.

### Resist Film Pattern Forming Process S120

FIG. 9 shows an explanatory view of a resist film pattern forming process S120.

Next, as shown in FIG. 9, the resist film pattern forming process S120 is performed to pattern the photoresist film 85a formed to be superimposed on the metallic film 84 using a photolithography technology.

A photomask 86 includes a photo substrate 87 formed of glass or the like, which has a light transmitting property, and a light shielding film pattern 87b that is formed of chrome or the like, which has a light shielding property, and that is formed on a principal surface 87a of the photo substrate 87. The light shielding film pattern 87b is used to pattern the photoresist film 85a, and is formed in an area excluding an area corresponding to the external shape of the piezoelectric vibrating reed 4, on the principal surface 87a of the photo substrate 87.

In the resist film pattern forming process S120, the photomask 86 is set to both surfaces of the square wafer 65 and is irradiated with ultraviolet rays R to expose the surfaces. As described above, as the photoresist material 85 in this embodiment, a negative resist material in which the photoresist film 85a in an area exposed to the ultraviolet rays is cured is used. Therefore, when being dipped in a development solution after the exposure, only the photoresist film 85a in an area that is not exposed by the ultraviolet rays and is not cured is selectively removed.

Here, when variation in the film thickness of the photoresist film 85a occurs and thereby an area in which the film thickness is large is present, even when the photoresist film 85a is exposed, the photoresist film 85a is not cured sufficiently, and therefore there is a concern in that the photoresist film 85a is dissolved and removed at the time of the development. In addition, since the surface defect occurs in the resist film pattern of the remained photoresist film 85a, this surface defect may cause a failure at the time of forming the external shape of the piezoelectric vibrating reed 4.

However, in this embodiment, adhesion of floating matter onto the first and second surfaces 65a and 65b of the square wafer 65 is suppressed in the photoresist film forming process S116, such that the photoresist film 85a is formed while the variation in the film thickness of the photoresist film 85a is suppressed. Therefore, in the resist film pattern forming process S120, it is possible to form a resist film pattern 85b without having the surface defect (refer to FIG. 10).

### Metallic Film Pattern Forming Process S122

FIG. 10 shows an explanatory view of the metallic film pattern forming process S122.

Next, the metallic film pattern forming process S122 is performed to pattern the metallic film 84, which is formed in the metallic film forming process S112, using the resist film pattern 85b of the remained photoresist film 85a as a resist mask. In this process, the metallic film 84 that is not masked by the resist film pattern 85b is selectively removed through etching. Then, the resist film pattern 85b is removed. In this manner, a metallic film pattern 84c corresponding to the external shape of the piezoelectric vibrating reed 4 is formed on the first and second surfaces 65a and 65b of the square wafer 65.

### Square Wafer Etching Process S124

FIG. 11 shows an explanatory view of the square wafer etching process S124.

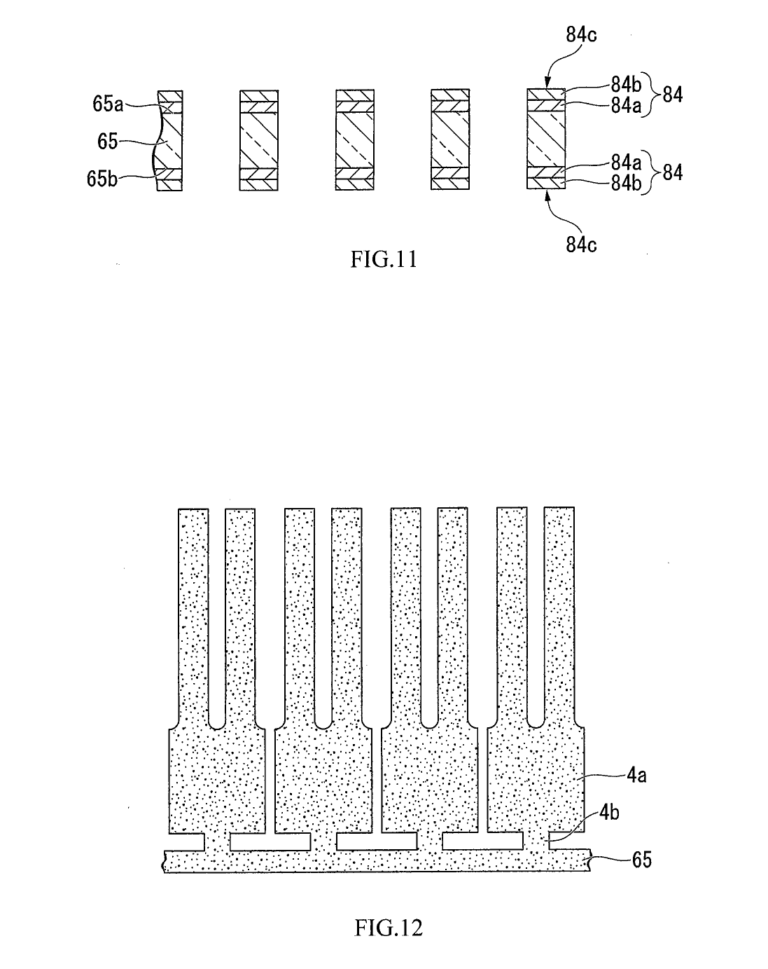

FIG. 12 shows an explanatory view of the square wafer 65 after being etched.

Next, as shown in FIG. 11, the square wafer etching process S124 is performed to etch the square wafer 65 on both surfaces of the square wafer 65 by using the metallic film pattern 84c as a metallic mask. In this manner, an area that is not masked with the metallic film pattern 84c is selectively removed, and therefore it is possible to form piezoelectric plates 4a having the external shape of the piezoelectric vibrating reed 4 (refer to FIG. 12). In addition, as shown in FIG. 12, each of the piezoelectric plates 4a is connected to the square wafer 65 after being etched through each of connecting portions 4b.

Then, the external shape forming process S110 is terminated.

### Vibrating Arm Groove Portion Forming Process S130

Next, the vibrating arm groove portion forming process S130 is performed to form the concave portion that will serve as the vibrating arm groove portion 18 (refer to FIG. 1) in each of the piezoelectric plates 4a. Specifically, a photoresist film (not shown) is formed on a surface of each of the piezoelectric plates 4a through a spray coating method or the like, and the photoresist film is patterned by a photolithography technology. Subsequently, the metallic film 84 is etched by using the resist film pattern as a resist mask, and the metallic film 84 is patterned in a state where a vibrating arm groove 18 forming area is opened. Then, the square wafer 65 is etched by using the metallic film 84 as a metallic mask, and then the metallic film 84 is removed. In this manner, it is possible to form the vibrating arm groove portion 18 on a principal surface of each of the piezoelectric plates 4a. Then, the vibrating arm groove portion forming process S130 is terminated.

Electrode or the like Forming Process S140

Next, the electrode or the like forming process S140 is performed to form an electrode or the like with the external shape of the piezoelectric vibrating reed 4 on an external surface of the piezoelectric plates 4a. In the electrode or the like forming process S140, first, the formation of the metallic film and the patterning are performed, the excitation electrode 15, the lead-out electrodes 19 and 20, the mounting electrodes 16 and 17, and the heavy metallic film 21 (refer to FIG. 1) are formed. Next, a coarse adjustment of a resonance frequency of the piezoelectric plates 4a is performed. This coarse adjustment is performed as follows. A coarse adjustment film 21a of the heavy metallic film 21 is irradiated with laser beams to evaporate a part of the coarse adjustment film 21a and to change the weight of the vibrating arm portions 10 and 11. Then, the electrode or the like forming process S140 is terminated.

### Small Piece Process S150

Finally, as shown in FIG. 12, the small piece process S150 is performed to cut each of the connecting portions 4b that connect the square wafer 65 and the respective piezoelectric plates 4a so as to detach the plurality of piezoelectric vibrating reeds 4 from the square wafer 65 and make the piezoelectric vibrating reeds 4 into a small piece. In this manner, a plurality of tuning fork type piezoelectric vibrating reeds 4 may be manufactured from one sheet of square wafer 65 at a time. At this point of time, the process of manufacturing the piezoelectric vibrating reeds 4 is terminated, and the plurality of piezoelectric vibrating reeds 4 may be obtained.

### Effect

According to this embodiment, the plurality of groove portions 90 are formed on the upper surface 88a of the flow regulating plate 88, such that the turbulent flow F flowing from the outer side to the inner side in the radial direction under the square wafer 65 may be trapped inside the groove portions 90 to form a residue therein. Therefore, it is possible to suppress the inflow of the turbulent flow F to an area located at the inner side in the radial direction in relation to the groove portions 90.

In addition, among the plurality of groove portions 90, the diameter of the outer side surface 91a of the first groove portion 91 is set to be smaller than the longest distance α from the rotation center K to the outer edge 66 of the square wafer 65, and is set to be larger than the shortest distance β from the rotation center K to the outer edge 66 of the square wafer 65. In this state, it is possible to suppress the inflow of the turbulent flow F to the inner side area in the radial direction in relation to the first groove portion 91, under the square wafer 65, which is the inner side in the radial direction in relation to the short side 66b side end of the oblique side 66c having the longest distance α from the rotation center K.

In addition, among the plurality of groove portions 90, the diameter of the outer side surface 92a of the second groove portion 92 is set to be smaller than the shortest distance β from the rotation center K to the outer edge 66 of the square wafer 65. In this manner, it is possible to suppress the inflow of the turbulent flow F to the inner side area in the radial direction in relation to the second groove portion 92, under the square wafer 65, which is the inner side in the radial direction in relation to the center portion of the long side 66a having the shortest distance 13 from the rotation center K.

When the first and second groove portions 91 and 92 are formed in this manner, it is possible to suppress the inflow of the turbulent flow F within a wide range over substantially the entire periphery of the square wafer 65. Therefore, it is possible to suppress the inflow of floating matter, which is transported due to the turbulent flow F, to the lower side of the square wafer 65, and adhesion of floating matter to the second surface 65b of the square wafer 65. As a result, the variation in the film thickness at the time of forming the photoresist film 85a on the square wafer 65 is suppressed, and thereby it is possible to suppress the occurrence of defects at the time of forming an external shape of the piezoelectric vibration reed 4.

Here, in the case of manufacturing a semiconductor device, the resist pattern is formed only on a surface (corresponding to the first surface 65a in this embodiment) of a semiconductor substrate, and only this surface of the semiconductor substrate is frequently used. Therefore, floating matter adhering to a rear surface (corresponding to the second surface 65b in this embodiment) of the semiconductor substrate may be removed through a polishing.

Contrary to this, in the case of forming the external shape of the piezoelectric vibrating reeds 4, since the entirety of the square wafer 65 is used as described above, the photoresist film 85a is formed on the first and second surfaces 65a and 65b. Therefore, floating matter adhering to the second surface 65b before the photoresist film 85a is formed is difficult to remove by polishing, and an additional process such as an application of a rinse solution or blowing of N2 is necessary to remove the adhered floating matter. In addition, after the front and back inverting process S118, when the photoresist film 85a is formed on the second surface 65b in the photoresist film forming process S116 that is performed again, in a case where floating matter adheres to the first surface 65a on which the photoresist film 85a is already formed, it is very difficult to remove the adhered floating matter.

However, according to this embodiment, when the first and second groove portions 91 and 92 are formed, it is possible to suppress the inflow of the turbulent flow F within a wide range over substantially the entire periphery of the square wafer 65, such that it is possible to suppress adhesion of floating matter onto the second surface 65b of the square wafer 65. In this manner, the present invention in which floating matter is reliably prevented from adhering onto the second surface 65b of the square wafer 65 is particularly effective for the formation of the external shape of the piezoelectric vibrating reeds 4.

In addition, according to this embodiment, the variation in the film thickness of the photoresist film 85a is suppressed by the manufacturing method described above, such that it is possible to form the piezoelectric vibrating reeds 4 with good accuracy. Therefore, the number of piezoelectric vibrating reeds 4 that are discarded due to failure in the external shape decreases, such that the manufacturing cost of the piezoelectric vibrating reeds 4 may be lowered.

### First Modification of Embodiment

### Flow Regulating Plate in which Heights of Wall Portions are Different from Each Other

Next, a flow regulating plate 88 according to a first modification of the embodiment will be described.

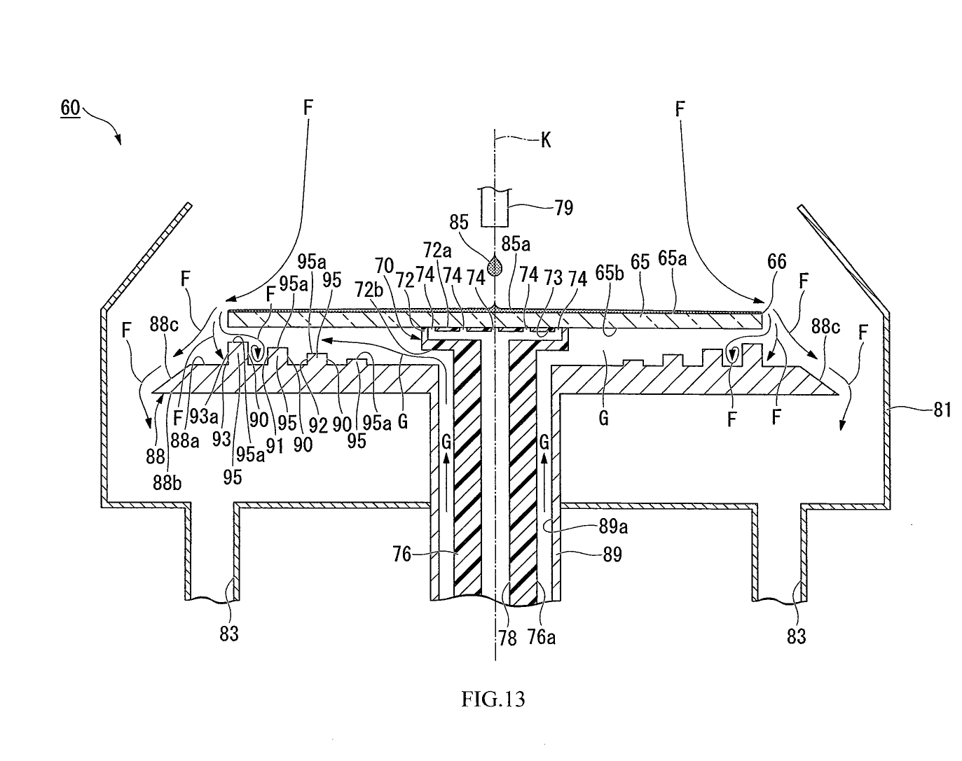

FIG. 13 shows an explanatory view of the flow regulating plate 88 according to the first modification of the embodiment.

In the above-described embodiment, the respective wall portions 95 are formed to have substantially the same height as each other. Contrary to this, as shown in FIG. 13, this first modification is different from the embodiment in that respective wall portions 95 are formed to have heights different from each other. In addition, descriptions with respect to portions having the same configuration as the embodiment will not be repeated.

In this modification, the respective wall portions 95 are formed to have heights different from each other. Specifically, as they go from the inner side to the outer side in the radial direction, the height of each of the wall portion 95 gradually enlarges. That is, as they go toward the outer side in the radial direction, the gap between the second surface 65b of the square wafer 65 and the wall portion 95 becomes narrow. Therefore, at the outer side in the radial direction, the flow rate of the airflow G that flows at the gap between the second surface 65b of the square wafer 65 and the wall portion 95 may be increased. Due to this, even when the turbulent flow F is apt to flow to the lower side of the square wafer 65, the turbulent flow F is pushed back, such that it is possible to suppress the inflow of the turbulent flow F. Therefore, it is possible to further suppress the inflow of floating matter, which is transported due to the turbulent flow F, to the lower side of the square wafer 65, and adhesion of floating matter to the second surface 65b of the square wafer 65. In addition, the height of each of the wall portions 95 is set depending on the flow rate of the airflow G, which is required.

### Second Modification of Embodiment

### Flow Regulating Plate in which an Upper End Surface of a Wall Portion is Inclined

Next, a flow regulating plate 88 according to a second modification of the embodiment will be described.

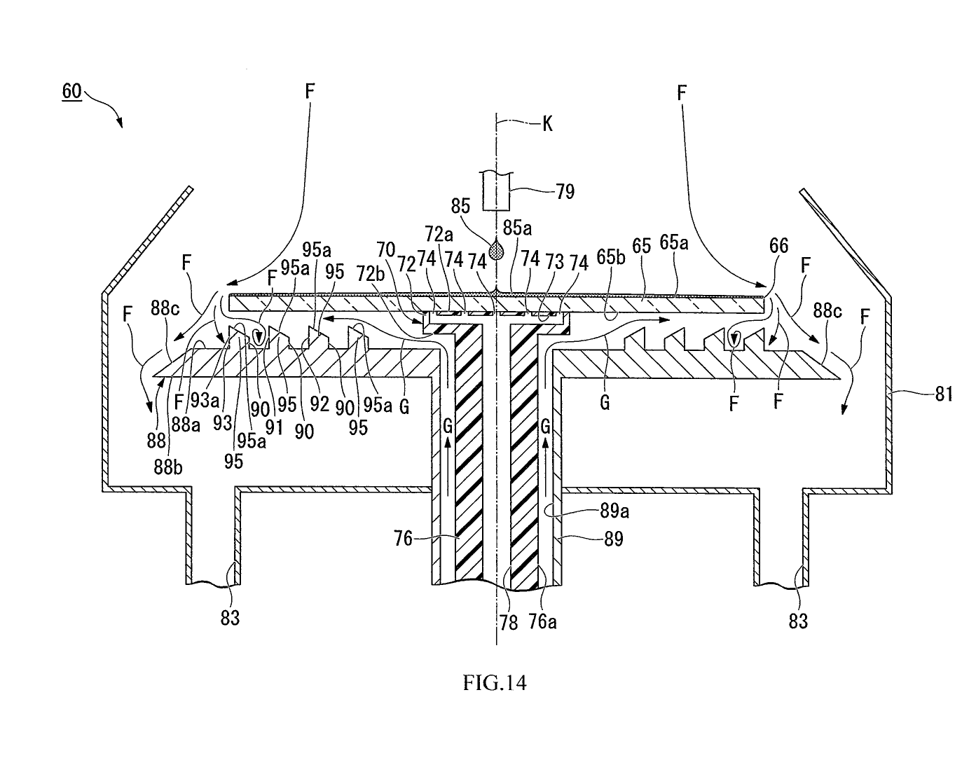

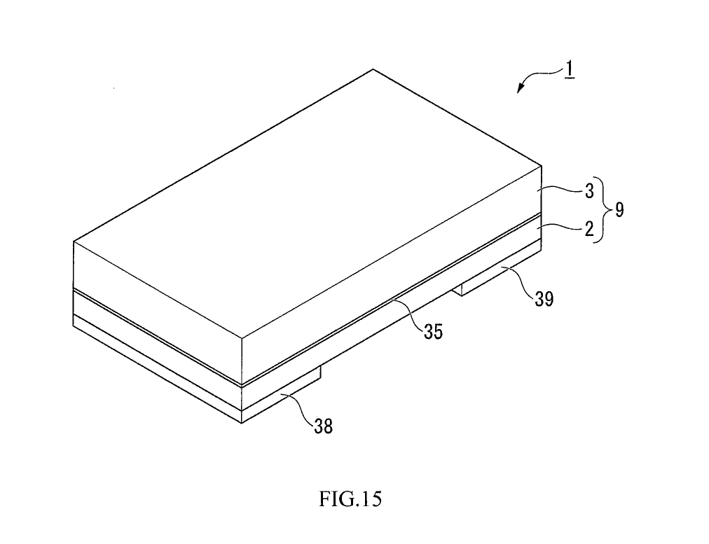

FIG. 14 shows an explanatory view of the flow regulating plate 88 according to the second modification of the embodiment.

In the above-described embodiment, upper end surfaces 95a of the respective wall portions 95 are formed horizontally. Contrary to this, as shown in FIG. 14, the second modification of the embodiment is different from the embodiment in that the upper end surfaces 95a of the respective wall portions 95 are formed to be inclined. In addition, descriptions with respect to portions having the same configuration as the embodiment will not be repeated.

The upper end surfaces 95a of the respective wall portions 95 are formed of inclined surfaces that become high as they go from the inner side to the outer side in the radial direction. That is, as they go toward the outer side in the radial direction, the gap between the second surface 65b of the square wafer 65 and the upper end surface 95a of the wall portion 95 becomes narrow.

Here, similarly to the above-described first modification, at the outer side in the radial direction, the flow rate of the airflow G that flows at the gap between the second surface 65b of the square wafer 65 and the wall portion 95 may be increased. Due to this, even when the turbulent flow F is apt to flow to the lower side of the square wafer 65, the turbulent flow F is pushed back, such that it is possible to suppress the inflow of the turbulent flow F. Therefore, it is possible to further suppress the inflow of floating matter, which is transported due to the turbulent flow F, to the lower side of the square wafer 65, and adhesion of floating matter to the second surface 65b of the square wafer 65. In addition, an angle of inclination in the upper end surface 95a of the wall portion 95, a clearance between the upper end surface 95a and the square wafer 65, or the like are set depending on the flow rate of the airflow G, which is required.

### Piezoelectric Vibrator

Next, a piezoelectric vibrator 1 as a package 9 including the piezoelectric vibrating reed 4 manufactured by the above-described manufacturing method will be described.

FIG. 15 shows an external perspective view of a piezoelectric vibrator 1.

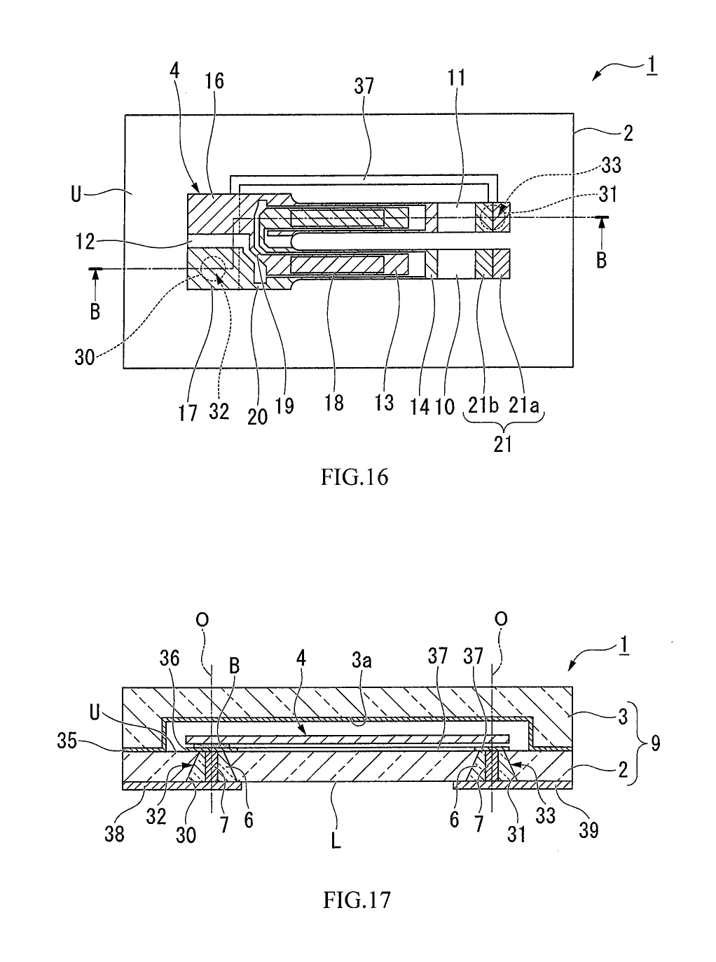

FIG. 16 shows an internal configuration diagram of the piezoelectric vibrator 1, in which a state where a lid substrate 3 is detached is shown in a plan view.

FIG. 17 shows a cross-sectional view taken along a B-B line in FIG. 16.

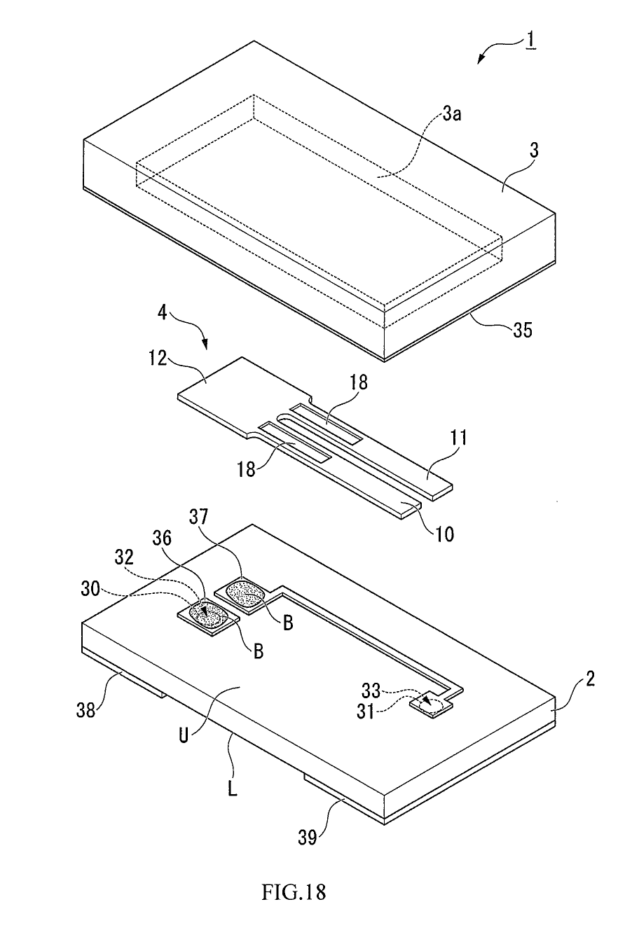

FIG. 18 shows an exploded perspective view of the piezoelectric vibrator 1 shown in FIG. 15.

In addition, in FIG. 18, the excitation electrodes 13 and 14, the lead-out electrodes 19 and 20, the mounting electrodes 16 and 17, and the heavy metallic film 21 that are described later are omitted for easy understanding of drawings.

As shown in FIG. 15, the piezoelectric vibrator 1 of this embodiment is a surface-mounting type piezoelectric vibrator 1 including a package 9 in which a base substrate 2 and the lid substrate 3 are anodically bonded through a bonding film 35, and a piezoelectric vibrating reed 4 that is accommodated in a cavity 3a of the package 9.

As shown in FIG. 17, the base substrate 2 and the lid substrate 3 are anodically bondable substrates that are formed of a glass material, for example, a soda-lime glass, and are formed to have a substantially plate shape. The cavity 3a that accommodates the piezoelectric vibrating reed 4 is formed in the lid substrate 3 at a bonding surface side with the base substrate 2.

The bonding film 35 (adhesive) for an anodic bonding is formed on the lid substrate 3 at the entirety of a bonding surface side with the base substrate 2. The bonding film 35 is formed at a frame region at the periphery of the cavity 3a in addition to the entirety of the internal surface of the cavity 3a. The bonding film 35 of this embodiment is formed of aluminum, but the bonding film 35 may be formed of chrome, silicon, or the like. This bonding film 35 and the base substrate 2 are anodically bonded and thereby the cavity 3a is vacuum-sealed.

The piezoelectric vibrator 1 includes penetration electrodes 32 and 33 that penetrates through the base substrate 2 in a thickness direction and conducts an inner side of the cavity 3a and an outer side of the piezoelectric vibrator 1. The penetration electrodes 32 and 33 include a metallic pin 7 that is disposed in penetration holes 30 and 31 penetrating through the base substrate 2 and electrically connects the piezoelectric vibrating reed 4 and the outside, and a barrel 6 that is filled between the penetration holes 30 and 31 and the metallic pin 7. In addition, hereinafter, the penetration electrode 32 is described as an example, but this is true of the penetration electrode 33. In addition, an electrical connection of the penetration electrode 33, a lead-out electrode 37, and an external electrode 39 is also true of an electrical connection of the penetration electrode 32, a lead-out electrode 36, and an external electrode 38.

The penetration hole 30 is formed in such a manner that an internal shape thereof becomes gradually large as it goes from upper surface U side to lower surface L side of the base substrate 2, and a cross-sectional shape including the center axis 0 of the penetration hole 30 becomes a tapered shape.

The metallic pin 7 is a conductive rod-shaped member that is formed of a metallic material such as a silver or nickel alloy, and aluminum, and is formed through a forging or a press working. It is preferable that the metallic pin 7 be formed of metal having a linear expansion coefficient that is close to that of a glass material of the base substrate 2, for example, an alloy (42 alloy) containing 58 wt % of iron, and 42 wt % of nickel.

The barrel 6 is formed by baking a glass frit having a paste shape. The metallic pin 7 is disposed in the barrel 6 so as to penetrate through the barrel 6 at the center of the barrel 6. The barrel 6 is strongly fixed with respect to the metallic pin 7 and the penetration hole 30.

As shown in FIG. 18, the pair of lead-out electrodes 36 and 37 are patterned at the upper surface U side of the base substrate 2. In addition, a bump B formed of metal or the like is provided on the pair of lead-out electrodes 36 and 37, respectively, and a pair of mounting electrodes of the piezoelectric vibrating reed 4 are mounted by using this bump B. In this manner, one side mounting electrode 17 (refer to FIG. 16) of the piezoelectric vibrating reed 4 is electrically connected to the one side penetration electrode 32 through the one side lead-out electrode 36, and the other side mounting electrode 16 (refer to FIG. 16) is electrically connected to the other side penetration electrode 33 through the other side lead-out electrode 37.

The pair of external electrodes 38 and 39 are formed on the lower surface L of the base substrate 2. The pair of external electrodes 38 and 39 are formed at both ends of the base substrate 2 in the longitudinal direction, and are electrically connected with respect to the pair of penetration electrodes 32 and 33.

In the case of operating the piezoelectric vibrator 1 configured in this manner, a predetermined driving voltage is applied with respect to the external electrodes 38 and 39 formed on the base substrate 2. In this manner, a voltage may be applied to the first excitation electrode 13 and the second excitation electrode 14 of the piezoelectric vibrating reed 4, such that it is possible to vibrate the pair of vibrating arm portions 10 and 11 with a predetermined frequency in a direction close to each other or in a direction departing from each other. In addition, the piezoelectric vibrating reed 4 may be used as a time of day source or a timing source of a control signal, a reference signal source, or the like by using the vibration of this pair of vibrating arm portions 10 and 11.

### Effect

According to the invention, an inexpensive piezoelectric vibrating reed 4 is included, such that it is possible to obtain an inexpensive piezoelectric vibrator 1.

### Oscillator

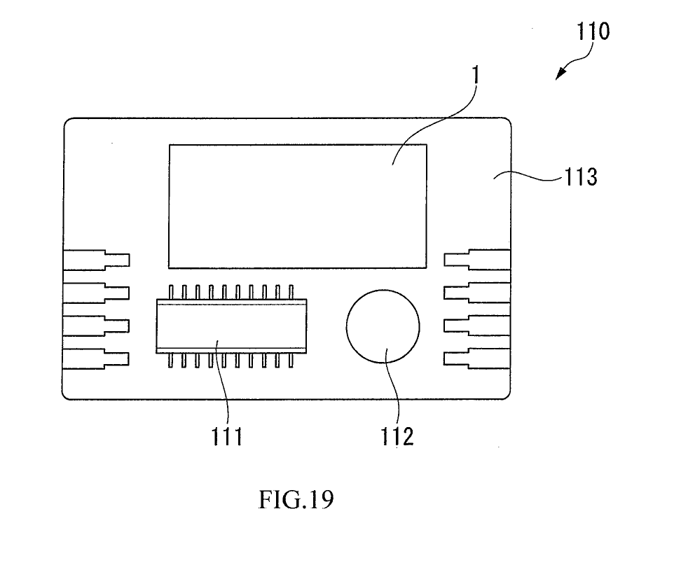

Next, an embodiment of an oscillator related to the invention will be described with reference to FIG. 19.

As shown in FIG. 19, an oscillator 110 of this embodiment is configured using the piezoelectric vibrator 1 as an oscillating element electrically connected to an integrated circuit 111. The oscillator 110 includes a substrate 113 in which an electronic element part 112 such as a condenser is mounted. The integrated circuit 111 for an oscillator is mounted in the substrate 113, and a piezoelectric vibrating reed of the piezoelectric vibrator 1 is mounted in the vicinity of the integrated circuit 111. The electronic element part 112, the integrated circuit 111, and the piezoelectric vibrator 1 are electrically connected to each other through an interconnection pattern (not shown). In addition, respective configuration parts are molded with a resin (not shown).

In the oscillator 110 configured in this manner, when a voltage is applied to piezoelectric vibrator 1, the piezoelectric vibrating reed in the piezoelectric vibrator 1 vibrates. This vibration is converted into an electric signal by a piezoelectric characteristic which the piezoelectric vibrating reed possesses, and is input to the integrated circuit 111 as an electric signal. The input electric signal is subjected to various treatments by the integrated circuit 111, and is output as a frequency signal. In this manner, the piezoelectric vibrator 1 functions as an oscillating element.

In addition, in regard to the configuration of the integrated circuit 111, for example, when an RTC (real time clock) module or the like is selectively set according to a request, a function of controlling an operation date or a time of a corresponding apparatus or an external apparatus, a function of providing a time of day or a calendar, or the like may be added, in addition to a simple functional oscillator for a timepiece, or the like.

According to the oscillator 110 of this embodiment, the inexpensive piezoelectric vibrator 1 is included, such that it is possible to provide an inexpensive oscillator 110.

### Electronic Apparatus

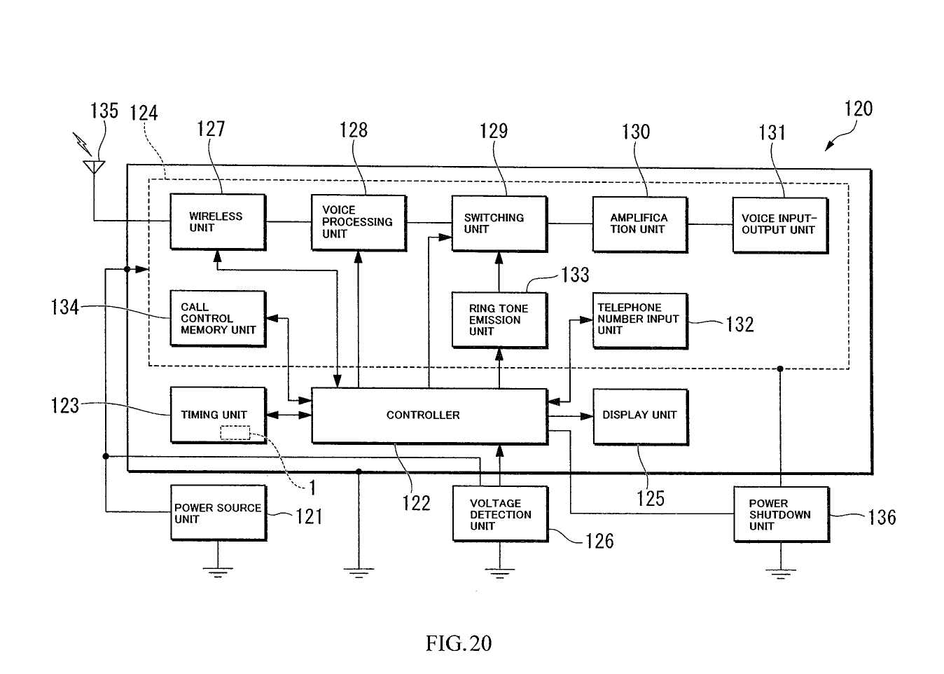

Next, an embodiment of an electronic apparatus related to the invention will be described with reference to FIG. 20. In addition, as an electronic apparatus, a portable information apparatus 120 including the above-described piezoelectric vibrator 1 is described as an example.

First, a portable information apparatus 120 of this embodiment is, for example, represented by a cellular phone, and is developed and modified from a watch in the related art. The external appearance is similar to the watch, and a liquid crystal display is disposed at a portion corresponding to a clock face, and the current time of day or the like can be displayed on the screen of this display. In addition, when being used as a communication apparatus, the portable information apparatus 120 is detached from a wrist, and a communication similar to a cellular phone in the related art may be realized by using a speaker and a microphone that are embedded in an inner side of a band. However, a significant reduction in size and weight is realized compared to the cellular phone in the related art.

Next, a configuration of the portable information apparatus 120 according to this embodiment will be described. As shown in FIG. 20, this portable information apparatus 120 includes a piezoelectric vibrator 1, and a power supply unit 121 that supplies power. The power supply unit 121 is, for example, configured by a lithium secondary battery. A control unit 122 that performs various controls, a time counting unit 123 that counts the time of day, a communication unit 124 that performs communication with the outside, a display unit 125 that displays a variety of information, and a voltage detecting unit 126 that detects a voltage of various functional units are connected in parallel to the power supply unit 121. In addition, power is supplied to respective functional units by the power supply unit 121.

The control unit 122 performs an operation control of the entirety of the system such as transmission or reception of voice data, measurement of the current time of day, a display, or the like by controlling the respective functional units. In addition, the control unit 122 includes a ROM in which a program is written in advance, a CPU that reads out a program written in the ROM and executes the program, a RAM that is used as a work area of the CPU, or the like.

The time measurement unit 123 includes an integrated circuit in which an oscillation circuit or a register circuit, a counter circuit, an interface circuit, or the like are embedded, and the piezoelectric vibrator 1. When a voltage is applied to the piezoelectric vibrator 1, the piezoelectric vibrating reed vibrates, and this vibration is converted into an electric signal due to a piezoelectric characteristic which crystal possesses, and is input to the oscillation circuit as an electric signal. An output of the oscillation circuit is made into a binary value, and is measured by the register circuit and the counter circuit. In addition, the time counting unit 123 transmits and receives a signal to and from the control unit 122 through the interface circuit, and the current time of day, the current date, calendar information, and the like are displayed on the display unit 125.

The communication unit 124 has the same function as a cellular phone in the related art, and includes a wireless unit 127, a voice processing unit 128, a switching unit 129, an amplifying unit 130, a voice input and output unit 131, a phone number input unit 132, a ringtone generating unit 133, and a call control memory unit 134.

The wireless unit 127 transmits and receives a variety of data such as voice data to and from a base station through an antenna 135. The voice processing unit 128 encodes and decodes a voice signal input from the wireless unit 127 or the amplifying unit 130. The amplifying unit 130 amplifies a signal input from the voice processing unit 128 or the voice input and output unit 131 to a predetermined level. The voice input and output unit 131 includes a speaker, a microphone, or the like, and amplifies a ringtone or a received voice, or picks up a voice.

In addition, the ringtone generating unit 133 generates a ringtone according to a call from the base station. The switching unit 129 switches the amplifying unit 130 connected to the voice processing unit 128 to the ringtone generating unit 133 only at the time of being called, and thereby the ringtone generated in the ringtone generating unit 133 is output to the voice input and output unit 131 through the amplifying unit 130.

In addition, the call control memory unit 134 stores a program related to calling call and called call control of a communication. In addition, the phone number input unit 132 includes, for example, number keys from 0 to 9 and keys other than the number keys, and when these number keys are pressed, the phone number of a call destination, or the like is input.

When a voltage that is added to respective functional units such as the control unit 122 by the power supply unit 121 is less than a predetermined value, the voltage detecting unit 126 detects this voltage drop and informs the control unit 122 of this voltage drop. The predetermined voltage value at this time is a value, which is set in advance as a minimum voltage necessary for stably operating the communication unit 124, and is, for example, substantially 3 V. The control unit 122 that is informed of the voltage drop from the voltage detecting unit 126 prohibits the operation of the wireless unit 127, the voice processing unit 128, the switching unit 129, and the ringtone generating unit 133. Particularly, the operation stop of the wireless unit 127 in which power-consumption is largest is requisite. In addition, a notice, which indicates that the communication unit 124 is unavailable due to a deficiency in the battery residual quantity, is displayed on the display unit 125.

That is, the operation of the communication unit 124 is prohibited by the voltage detecting unit 126 and the control unit 122, and the notice thereof may be displayed on the display unit 125. This display may be realized by a text message, but as a relatively intuitive display, a telephone icon, which is displayed at an upper part of a display surface of the display unit 125, may be attached with x (false) mark.

In addition, when a power interruption unit 136 that selectively interrupts the power of a portion related to the function of the communication unit 124 is provided, it is possible to reliably stop the function of the communication unit 124.

According to the mobile information apparatus 120 of this embodiment, the inexpensive piezoelectric vibrator 1 is included, such that it is possible to provide an inexpensive portable information apparatus 120.

### Radio-Controlled Timepiece

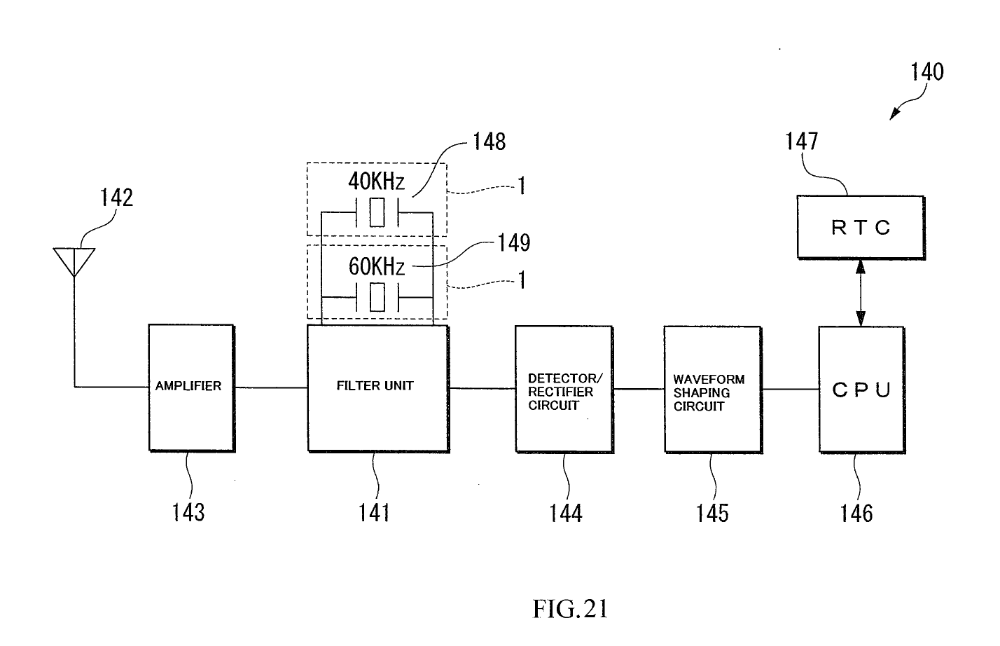

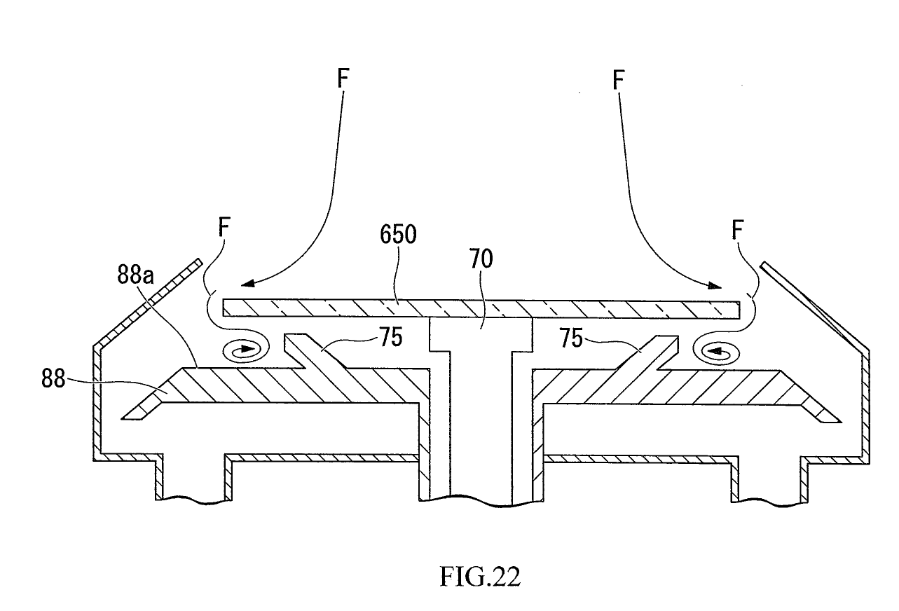

Next, an embodiment of a radio-controlled timepiece related to the invention will be described with reference to FIG. 21.

As shown in FIG. 21, the radio-controlled timepiece 140 according to this embodiment includes a piezoelectric vibrator 1 that is electrically connected to a filter unit 141. The radio-controlled timepiece 140 is a timepiece that has a function of receiving a standard radio wave including timepiece information and performing an automatic correction to an accurate time of day, and displays the accurate time of day.

In Japan, transmitting stations are located in Fukushima Prefecture (40 kHz) and Saga Prefecture (60 kHz), and the transmitting stations transmit a standard radio wave, respectively. A long wave such as 40 kHz or 60 kHz concurrently has a property of being propagated on the surface of the earth, and a property of being propagated while being reflected from the ionosphere and the surface of the earth together, such that the propagation range is wide, and covers the entirety of Japan with the above-described two transmitting stations.

Hereinafter, a functional configuration of the radio-controlled timepiece 140 will be described in detail.

An antenna 142 receives a standard radio wave that is a long wave of 40 kHz or 60 kHz. The standard radio wave that is a long wave is obtained by subjecting time of date information called a time code in an AM modulation to a carrier wave of 40 kHz or 60 kHz. The received standard radio wave that is a long wave is amplified by an amplifier 143, and is filtered and tuned by a filter unit 141 including a plurality of piezoelectric vibrators 1.

The piezoelectric vibrators 1 in this embodiment include crystal vibrator units 148 and 149 that have resonance frequencies of 40 kHz and 60 kHz that are the same as the carrier frequency, respectively.

In addition, a signal of a predetermined frequency that is filtered is detected and demodulated by a defecting and rectifying circuit 144.

Subsequently, the time code is fetched through a waveform shaping circuit 145, and is counted in a CPU 146. In the CPU 146, information such as the current year or an integration date, day of week, time of day, and the like are fetched. The fetched information is reflected on the RTC 147, and therefore accurate time of day information is displayed.

Since the carrier wave is 40 kHz or 60 kHz, as the crystal vibrator units 148 and 149, the vibrator having the above-described tuning fork type vibrator is suitable.

In addition, in the above description, an example in Japan is illustrated, but the frequency of the standard radio wave that is a long wave is different overseas. For example, in Germany, a standard radio wave of 77.5 kHz is used. Therefore, in a case where the radio-controlled timepiece 140 that is correspondent overseas is assembled in the portable apparatus, a piezoelectric vibrator 1 with a frequency different from the case of Japan is further necessary.

According to the radio-controlled timepiece 140 of this embodiment, the inexpensive piezoelectric vibrator 1 is included, such that it is possible to provide an inexpensive radio-controlled timepiece 140.

In addition, the invention is not limited to the above-described embodiments.

In the method of manufacturing the piezoelectric vibrating reed 4 according to the embodiment, the tuning fork type piezoelectric vibrating reed 4 is manufactured, but the piezoelectric vibrating reed 4 manufactured by the manufacturing method of the invention is not limited to the tuning fork type, and for example, may be an AT cut type piezoelectric vibrating reed (thickness shear vibrating reed). In addition, electronic parts other than the piezoelectric vibrating reed may be manufactured by the manufacturing method of the invention.

In the method of manufacturing the piezoelectric vibrating reed 4 according to this embodiment, a film of the photoresist material 85 is formed, but a masking material film other than the photoresist film 85a may be formed. In addition, as the photoresist material 85, a negative resist material is used, but the photoresist material 85 is not limited to the negative resist material, and a positive resist material may be used.

In the method of manufacturing the piezoelectric vibrating reed 4 of this embodiment, three groove portions 90 are formed on an upper surface 88a of the flow regulating plate 88, and four wall portion 95 are formed, but the numbers of the groove portions 90 and the wall portions 95 are not intended to be limited to this embodiment.

In addition, in this embodiment, the concave portion 93 is formed at an outer side in the radial direction in the first groove portion 91 of the flow regulating plate 88, but the concave portion 93 may not be formed. However, this embodiment has an advantage in that floating matter may adhere to the side wall surface 93a due to the concave portion 93, and thereby the inflow of floating matter to the lower side of the square wafer 65 may be suppressed.

What is claimed is:

1. A method of manufacturing a piezoelectric vibrating reed comprising:
providing a square wafer on a film forming apparatus; and
forming a masking material film on a first surface of the square wafer by rotating the square wafer about a central rotation axis of a wafer maintaining portion of a spin chuck,
wherein the square wafer is maintained on an upper surface of the wafer maintaining portion while a second surface of the square wafer faces downward, and a flow regulating plate projects beyond an outer edge of the square wafer and is disposed below the wafer maintaining portion of the spin chuck,
the flow regulating plate having a plurality of groove portions in an upper surface, which are concentric with each other with the respect to the central rotation axis and a plurality of wall portions, which are adjacent to each other in a radial direction of the respective groove portions, and
wherein, among the plurality of groove portions, the diameter of an outer side surface of a first groove portion is smaller than a longest distance from the central rotation axis to the outer edge of the square wafer and is larger than a shortest distance from the central rotation axis to an outer edge of the square wafer, and a diameter of an outer side surface of a second groove portion at an inner side in relation to the first groove portion is smaller than the shortest distance from the central rotation axis to the outer edge of the square wafer.

2. The method according to claim 1, wherein during rotating the square wafer, turbulent flow under the square wafer from an outer portion to an inner portion in the radial direction is trapped inside the groove portions, such that inflow of the turbulent flow to the inner portion is substantially suppressed.

3. The method according to claim 2, wherein floating matter in the turbulent flow is substantially trapped inside the groove portions.

4. The method according to claim 1, wherein the flow regulating plate further includes a concave portion on the upper surface thereof extending from the outer side surface of the first groove portion to an outer periphery of the flow regulating plate in the radial direction and extending over an entire periphery of the flow regulating plate.

5. The method according to claim 4, wherein the concave portion provides a side wall surface that faces the outer side surface of the first groove portion in the radial direction and, during rotating the square wafer, floating matter in a turbulent flow under the square wafer from an outer portion to an inner portion in the radial direction adheres to the side wall surface, such that an inflow of floating matter entrained in the turbulent flow to the second side of the square wafer is substantially suppressed.

6. The method according to claim 1 further comprising generating airflow radially from an inner region to an outer region in the radial direction between the upper surface of the flow regulating plate and the second surface of the square wafer during rotating the square wafer opposes turbulent flow from an outer portion to an inner portion of the square wafer in the radial direction and substantially suppresses an inflow of floating matter entrained in the turbulent flow.

7. The method according to claim 6, wherein a height of the plurality of the wall portions gradually increases from an inner portion to an outer portion of the flow regulating plate in the radial direction.

8. The method according to claim 6, wherein upper end surfaces of respective wall portions comprise inclined surfaces that increase in height from an inner portion to an outer portion of the flow regulating plate in the radial direction, and a gap between the second surface of the square wafer and the wall portions narrows in the radial direction.

9. An apparatus for forming a masking material film on a first surface of a square wafer during manufacturing a piezoelectric vibrating reed, the apparatus comprising:
a spin chuck that maintains the square wafer on an upper surface of a wafer maintaining portion while a second surface of the square wafer faces a downward and that rotates the square wafer about a central rotation axis of the wafer maintaining portion; and
a flow regulating plate that projects beyond an outer edge of the square wafer and that is disposed below the wafer maintaining portion, the flow regulating plate having a plurality of groove portions in an upper surface thereof, which are concentric with each other with respect to the central rotation axis, and having a plurality of wall portions, which are adjacent to each other in a radial direction of the respective groove portions,
wherein, among the plurality of groove portions, the diameter of an outer side surface of a first groove portion in the radial direction is smaller than a longest distance from the central rotation axis to the outer edge of the square wafer and is larger than a shortest distance from the central rotation axis to the outer edge of the square wafer, and the diameter of an outer side surface of a second groove portion at an inner side in relation to the first groove portion is smaller than the shortest distance from the central rotation axis to the outer edge of the square wafer.

10. The apparatus according to claim 9, wherein the plurality of groove portions are configured such that, during rotating the square wafer, turbulent flow under the square wafer from an outer portion to an inner portion in the radial direction is trapped inside the groove portions and an inflow of the turbulent flow to the inner portion of the square wafer is substantially suppressed.

11. The method according to claim 9, wherein the flow regulating plate further includes a concave portion on the upper surface thereof extending from the outer side surface of the first groove portion to an outer periphery of the flow regulating plate in the radial direction and extending over an entire periphery of the flow regulating plate.

12. The method according to claim 9, wherein a height of the plurality of the wall portions gradually increases from an inner portion to an outer portion of the flow regulating plate in the radial direction.

13. The method according to claim 9, wherein upper end surfaces of respective wall portions comprise inclined surfaces that increase in height from an inner portion to an outer portion of the flow regulating plate in the radial direction, and a gap between the second surface of the square wafer and the wall portions narrows in the radial direction.

14. A piezoelectric vibrating reed manufactured according to the method of claim 1.

15. A piezoelectric vibrator including a piezoelectric vibrating reed manufactured according to the method of claim 1.

16. An oscillator including the piezoelectric vibrator of claim 15 electrically connected to an integrated circuit as an oscillating element.

17. An electronic including the piezoelectric vibrator of claim 15 electrically connected to a time counting unit.

18. A radio-controlled timepiece including the piezoelectric vibrator of claim 15 electrically connected to a filter unit.
